(19) United States
(12) Patent Application Publication
(10) Pub. No.: US 2024/0365642 A1
(43) Pub. Date: Oct. 31, 2024

(54) DISPLAY APPARATUS AND METHOD FOR MANUFACTURING THE SAME

(71) Applicant: Samsung Display Co., Ltd., Yongin-si (KR)

(72) Inventors: WOOSUK SEO, Yongin-si (KR); TAEHO LEE, Yongin-si (KR)

(73) Assignee: Samsung Display Co., Ltd., Yongin-si (KR)

(21) Appl. No.: 18/420,045

(22) Filed: Jan. 23, 2024

(30) Foreign Application Priority Data
Apr. 25, 2023 (KR) 10-2023-0053722

(51) Int. Cl. H10K 59/80; B32B 5/02; B32B 15/08; B32B 15/14; B32B 15/18; B32B 27/28; C23C 14/02; C23C 14/20; C23C 14/35; H10K 59/12

(52) U.S. Cl. CPC H10K 59/80; B32B 5/02; B32B 15/08; B32B 15/14; B32B 15/18; B32B 27/281; C23C 14/021; C23C 14/205; C23C 14/35; H10K 59/1201; B32B 2255/205; B32B 2262/101; B32B 2262/106; B32B 2457/206

(57) ABSTRACT

A display apparatus includes a display panel including a base substrate, a circuit layer, and a light emitting element which are stacked on each other, and a support layer disposed below the base substrate and including a metal. The support layer has an elastic strain of about 2.5% or greater, and the support layer has a yield strength of about 1200 MPa or greater.

### CROSS-REFERENCE TO RELATED APPLICATION(S)

This U.S. non-provisional patent application claims priority to and benefits of Korean Patent Application No. 10-2023-0053722 under 35 U.S.C. § 119, filed on Apr. 25, 2023 in the Korean Intellectual Property Office, the entire contents of which are hereby incorporated by reference.

### BACKGROUND

### 1. Technical Field

This disclosure relates to a flexible display apparatus and a method for manufacturing the same.

### 2. Description of Related Art

Multimedia electronic devices such as televisions, mobile phones, tablets, navigation system units, and game consoles may include a display apparatus for displaying images. With the recent technology development of display apparatuses, various flexible display apparatuses which may be transformed into a curved surface shape, folded, or rolled are being developed. Flexible display apparatuses are able to be transformed into various shapes, and thus, are easy to carry, and may improve user convenience. Stacked members included in a flexible display apparatus are easily folded, rolled, or bent, and at the same time, are required to have physical properties for minimizing deformation of the display apparatus due to repeated folding, rolling, or bending.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

This disclosure provides a display apparatus with improved reliability by improving elastic restoration force and strength inside the display apparatus, thereby preventing damage or deformation even in case that the display apparatus is folded, rolled, or bent.

An embodiment of the disclosure provides a display apparatus that may include a display panel including a base substrate, a circuit layer, and a light emitting element which are stacked on each other, and a support layer disposed below the base substrate and including a metal. The support layer may have an elastic strain of about 2.5% or greater, and the support layer may have a yield strength of about 1200 MPa or greater.

In an embodiment, the support layer may include an alloy including two or more elements among aluminum (Al), zirconium (Zr), titanium (Ti), molybdenum (Mo), copper (Cu), nickel (Ni), yttrium (Y), cobalt (Co), and silicon (Si).

In an embodiment, the alloy may include at least one of aluminum (Al), zirconium (Zr), titanium (Ti), and molybdenum (Mo) in a highest atomic percent.

In an embodiment, the alloy may be at least one of Zr—Cu—Co, Zr—Cu—Si, Zr—Cu—Al—Ni, Al—Y—Ni—Co, Ti—Si—Zr—Mo, and Mo—Zr—Si—Ti.

In an embodiment, the alloy may be at least one of Zr—Cu—Co, Zr—Cu—Si, and Zr—Cu—Al—Ni, and an atomic percent of zirconium in the alloy may be in a range of about 50 at % to about 90 at %.

In an embodiment, the support layer may have an elastic strain in a range of about 4.6% to about 4.9%.

In an embodiment, the support layer may have a yield strength in a range of about 2700 MPa to about 2900 MPa.

In an embodiment, the alloy may be Al—Y—Ni—Co, and an atomic percent of aluminum in the alloy may be in a range of about 50 at % to about 85 at %.

In an embodiment, the support layer may have an elastic strain in a range of about 2.5% to about 2.8%.

In an embodiment, the support layer may have a yield strength in a range of about 1200 MPa to about 1400 MPa.

In an embodiment, the alloy may have a columnar-free amorphous structure.

In an embodiment, the base substrate may include a first surface on which the circuit layer is disposed, and a second surface opposing the first surface. The support layer may physically contact the second surface.

In an embodiment, the display apparatus may further include a synthetic resin film disposed below the display panel and including at least one of polyimide and polyethylene terephthalate, wherein the support layer may physically contact the synthetic resin film.

In an embodiment, the display panel and the support layer may be folded or rolled around an axis extended in a direction.

In an embodiment, the display apparatus may further include a support plate disposed below the display panel, and including stainless steel or a reinforced fiber, wherein the support layer may physically contact the support plate.

In an embodiment of the disclosure, a method for manufacturing a display apparatus may include providing a processing substrate, ion-etching a surface of the processing substrate, and forming a support layer including a metal on the ion-etched surface using a sputtering process. The support layer may have an elastic strain of about 2.5% or greater, and the support layer may have a yield strength of about 1200 MPa or greater.

In an embodiment, the sputtering process may be a high-frequency pulsed-DC magnetron sputtering process.

In an embodiment, in the high-frequency pulsed-DC magnetron sputtering process, a density of power applied to a target layer for forming the support layer including a metal may be in a range of about 4 W/cm² to about 5 W/cm².

In an embodiment, the target layer may be formed by manufacturing a master alloy by selecting an alloying element, forming metal powder from the master alloy, and sintering the metal powder. The alloying element may include two or more elements among aluminum (Al), zirconium (Zr), titanium (Ti), molybdenum (Mo), copper (Cu), nickel (Ni), yttrium (Y), cobalt (Co), and silicon (Si).

In an embodiment, a temperature at which the metal powder is sintered may be equal to or greater than a glass transition temperature of the alloying element, and the temperature at which the metal powder is sintered may be equal to or less than a crystallization temperature thereof.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a schematic perspective view of a display apparatus according to an embodiment of the disclosure;

FIG. 2A to FIG. 2C are schematic perspective views of a folded display apparatus according to an embodiment of the disclosure;

FIG. 3 is a schematic perspective view of a display apparatus according to an embodiment of the disclosure;

FIG. 4A and FIG. 4B are schematic perspective views of a slidable display apparatus according to an embodiment of the disclosure;

FIG. 5 is a schematic plan view of a display panel according to an embodiment of the disclosure;

FIG. 6 is a schematic cross-sectional view of a display apparatus according to an embodiment of the disclosure;

FIG. 7A to FIG. 7D are schematic cross-sectional views of a display apparatus according to an embodiment of the disclosure;

FIG. 8A to FIG. 8D are schematic cross-sectional views of a display apparatus according to an embodiment of the disclosure;

FIG. 9A to FIG. 9D are schematic cross-sectional views of a display apparatus according to an embodiment of the disclosure;

FIG. 10 is a flowchart of a method for manufacturing a display apparatus according to an embodiment of the disclosure;

FIG. 11 is a schematic cross-sectional view illustrating a step of forming a support layer according to an embodiment of the disclosure;

FIG. 12A to FIG. 12C are schematic cross-sectional structural images of a support layer of embodiments of the disclosure;

FIG. 13 is a schematic graph of tensile stress according to the strain of embodiments of the disclosure;

FIG. 14A is a schematic cross-sectional view illustrating a process of testing restoration force according to bending deformation of a measurement substrate; and

FIG. 14B is a schematic graph illustrating restoration force according to bending deformation of embodiments and a comparative embodiment.

### DETAILED DESCRIPTION OF THE EMBODIMENTS

The disclosure may be modified and presented in many alternate forms, and thus only a few specific embodiments will be disclosed in the drawings and described in detail. It should be understood, however, that these embodiments are not intended to limit the disclosure to the particular forms disclosed. Rather, this disclosure is intended to cover all modifications, equivalents, and alternatives falling within the spirit and scope thereof.

As used herein, the singular forms, “a,” “an,” and “the” are intended to include the plural forms as well, unless the context clearly indicates otherwise.

In the disclosure, when an element (or a region, a layer, a portion, etc.) is referred to as being “on,” “connected to,” or “coupled to” another element, it means that the element may be directly disposed on/connected to/coupled to the other element, or that a third element may be disposed therebetween.

Like reference numerals refer to like elements. Also, in the drawings, the thickness, the ratio, and the dimensions of elements may be exaggerated for an effective description of technical contents.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

It will be understood that, although the terms “first,” “second,” etc. may be used herein to describe various elements, these elements should not be limited by these terms. These terms are only used to distinguish one element from another. For example, a first element may be referred to as a second element, and a second element may also be referred to as a first element in a similar manner without departing the scope of rights of the disclosure.

In addition, terms such as “below,” “lower,” “above,” “upper,” and the like are used to describe the relationship of the elements shown in the drawings. The terms are used as a relative concept and are described with reference to the direction indicated in the drawings.

It should be understood that the terms “comprise,” “contain,” “include,” and “have” are intended to specify the presence of stated features, integers, steps, operations, elements, components, or combinations thereof in the disclosure, but do not preclude the presence or addition of one or more other features, integers, steps, operations, elements, components, or combinations thereof.

The term “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

“About” or “approximately” or “substantially” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

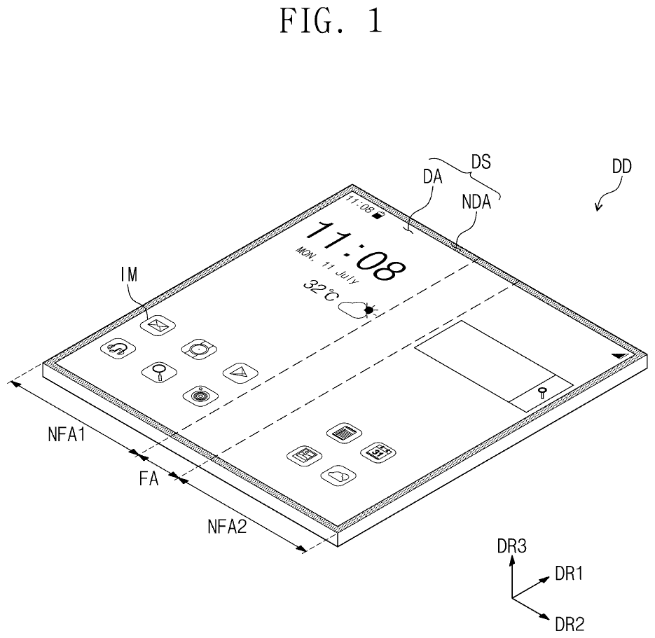

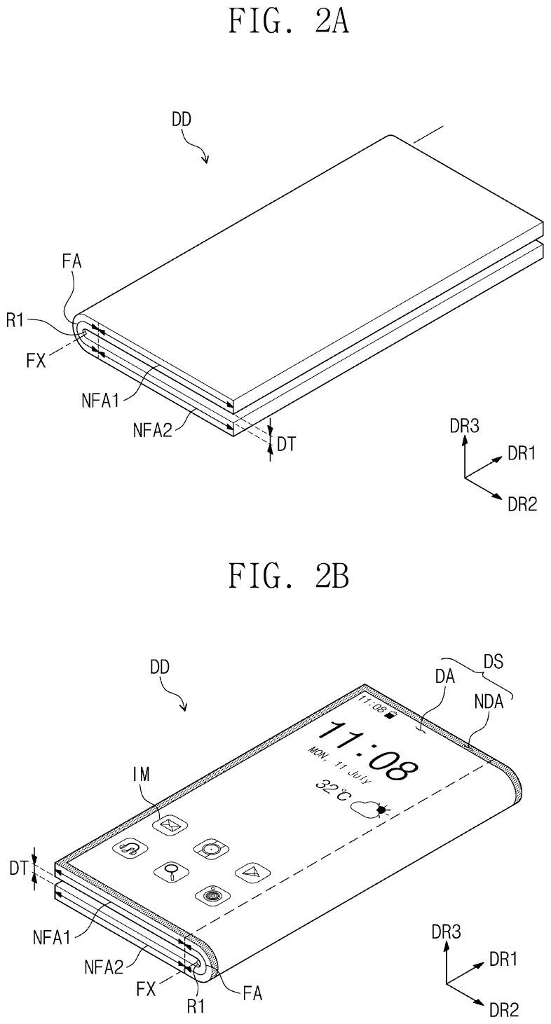

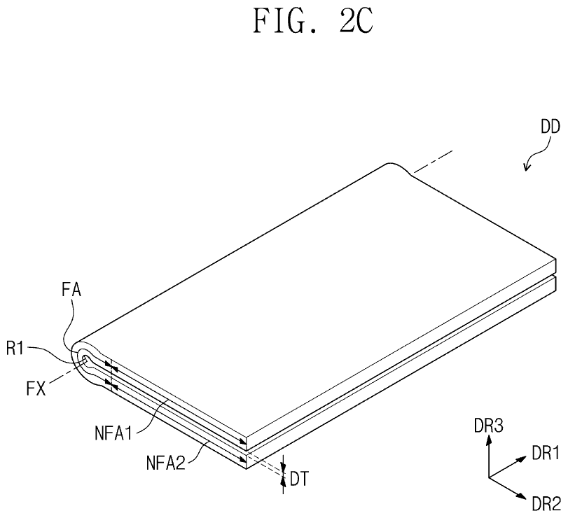

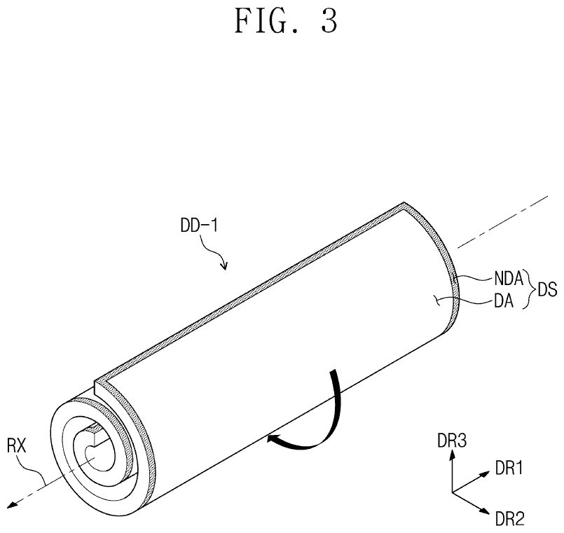

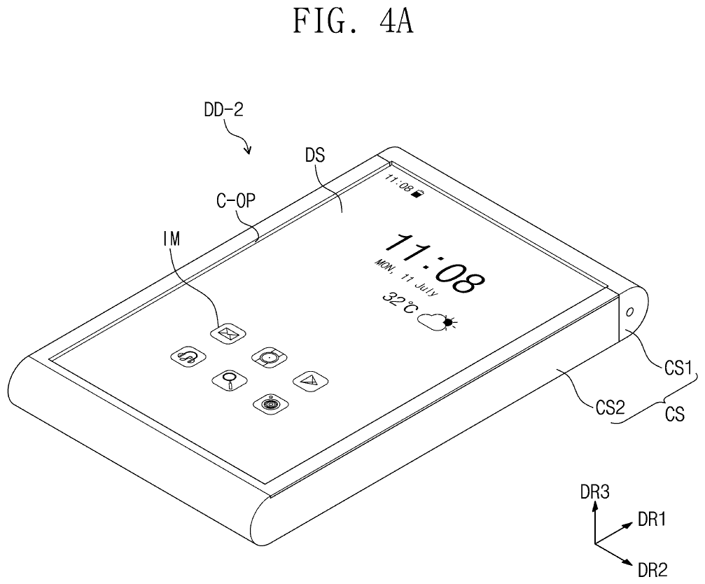

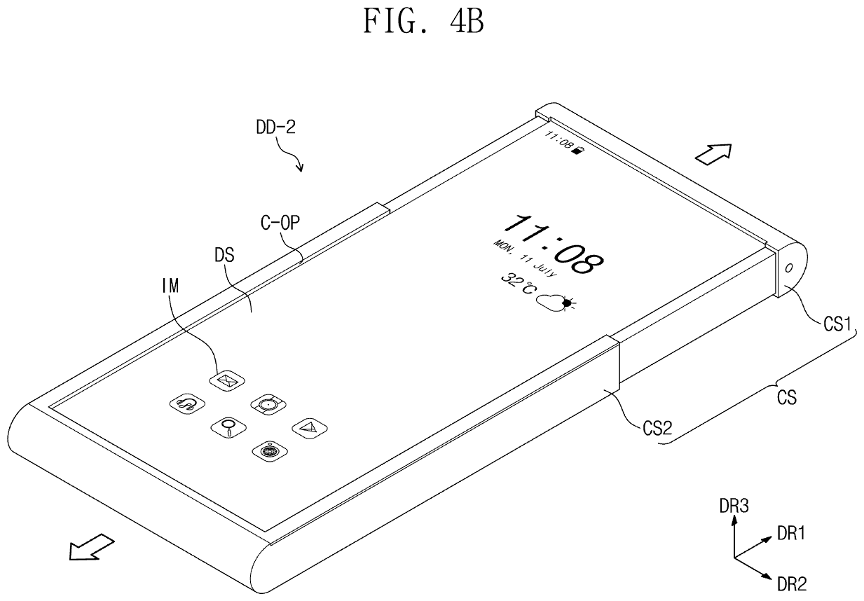

FIG. 1 is a schematic perspective view of a display apparatus DD according to an embodiment of the disclosure. FIG. 2A to FIG. 2C are schematic perspective views of the folded display apparatus DD according to an embodiment of the disclosure. FIG. 3 is a schematic perspective view of a rolled display apparatus DD-1 according to an embodiment of the disclosure. FIG. 4A and FIG. 4B are schematic perspective views of a slidable display apparatus DD-2 according to an embodiment of the disclosure.

Referring to FIG. 1 to FIG. 4B, the display apparatuses DD, DD-1, and DD-2 may be display apparatuses activated in response to an electrical signal and displaying an image IM. For example, the display apparatuses DD, DD-1, and DD-2 may be included in a large-sized device such as a television and an external billboard, as well as in a small-and-medium-sized device such as a monitor, a mobile phone, a tablet computer, a navigation system unit, and a game console. The embodiments of the display apparatuses DD, DD-1, and DD-2 are only examples, and the display apparatuses DD, DD-1, and DD-2 are not limited to any one thereof.

The display apparatuses DD, DD-1, and DD-2 of an embodiment may be flexible. Being “flexible” refers to having properties of being able to be bent, which may include from a structure of being completely folded to a structure of being able to be bent to a degree of a few nanometers. FIG. 2A to FIG. 4B illustrate various embodiments of the flexible display apparatuses DD, DD-1, and DD-2. For example, the display apparatuses DD, DD-1, and DD-2 may be a foldable display apparatus DD (see FIG. 2A to FIG. 2C), a rollable display apparatus DD-1, or a slidable display apparatus DD-2.

FIG. 1 illustrates a perspective view of the display apparatus DD in an unfolded state (or unfolded state). Referring to FIG. 1, the display apparatus DD may have a quadrangular shape with sides extended in a first direction DR1 and in a second direction DR2 in a plan view. However, the disclosure is not limited thereto, and the display apparatus DD may have various shapes in a plan view, such as a circular shape and a polygonal shape.

The display apparatus DD in an unfolded state may display an image IM toward a third direction DR3 through a display surface DS parallel to a plane defined by the first direction DR1 and the second direction DR2. The third direction DR3 may be defined as a direction perpendicular to the plane defined by the first direction DR1 and the second direction DR2. The front surface (or upper surface) and the rear surface (or lower surface) of members constituting the display apparatus DD may oppose each other in the third direction DR3, and a normal direction of each of the front surface and the rear surface may be substantially parallel to the third direction DR3.

A separation distance between the front surface and the rear surface, which is defined along the third direction DR3, may correspond to the thickness of a member. In the disclosure, “in a plan view” may be defined as a state viewed in the third direction DR3. In the disclosure, “in a cross-sectional view” may be defined as a state viewed in the first direction DR1 or in the second direction DR2. Directions indicated by the first to third directions DR1, DR2, and DR3 are a relative concept, and may be converted to different directions.

The display surface DS on which the image IM is displayed may correspond to the front surface of display apparatus DD. The image IM provided in the display apparatus DD may include both a moving image and a still image. FIG. 1 illustrates a clock and icons as an example of the image IM.

The display surface DS of the display apparatus DD may include a display portion DA and a non-display portion NDA. The display portion DA may be a region of the display surface DS displaying the image IM. The display apparatus DD may provide the image IM to a user through the display portion DA. The non-display portion NDA may be a region which does not display the image IM. The non-display portion NDA may have a predetermined or selected color, and may be a region having a lower light transmittance than the display portion DA.

The non-display portion NDA may be adjacent to the display portion DA, and the shape of the display portion DA may be defined by the non-display portion NDA. For example, the non-display portion NDA may surround the display portion DA. However, this is only an example, and the non-display portion NDA may be disposed adjacent to only one side of the display portion DA, or may be disposed on a side surface of the display apparatus DD, not the front surface thereof. However, the disclosure is not limited thereof, and the non-display portion NDA may be omitted.

The display apparatus DD may sense an external input applied from the outside. The external input may include various types of inputs provided from the outside of the display apparatus DD. For example, the external input may include force, pressure, temperature, light, and the like. The external input may include not only an input which comes into contact with the display apparatus DD (e.g., a contact by a user's hand or a contact by an electromagnetic pen), but also an input applied adjacent to the display apparatus DD at a predetermined or selected distance (e.g., hovering).

The display apparatus DD may sense an external input applied to the front surface of the display apparatus DD. However, a region of the display apparatus DD in which the external input is sensed is not limited to the front surface of the display apparatus DD, and the display apparatus DD may sense an external input applied to a side surface of a rear surface of the display apparatus DD.

The display apparatus DD may include a folding region FA and non-folding regions NFA1 and NFA2. FIG. 1 illustrates the display apparatus DD including a first non-folding region NFA1 and a second non-folding region NFA2. The folding region FA may be disposed between the first non-folding region NFA1 and the second non-folding region NFA2. In the unfolded state, the first non-folding region NFA1, the folding region FA, and the second non-folding region NFA2 of the display apparatus DD may be arranged along the second direction DR2.

The folding region FA may be a region which is flat, or bent with a predetermined or selected curvature, depending on a folding operation. For example, in the unfolded display apparatus DD, the folding region FA may be flat. The first and second non-folding regions NFA1 and NFA2 may be regions that remain flat in folded and unfolded states.

The folding region FA of the display apparatus DD may be folded around a folding axis extended along a direction. For example, as illustrated in FIG. 2A to FIG. 2C, the display apparatus DD may be folded along a folding axis FX extended in the first direction DR1. The folding axis FX may be extended in a direction parallel to long sides of the display apparatus DD, but is not limited thereto, and may be extended in a direction parallel to short sides of the display apparatus DD.

Referring to FIG. 2A and FIG. 2C, the folding axis FX may be defined on the front of the display apparatus DD. The display apparatus DD may be in-folded around the folding axis FX. Display surfaces DS (see FIG. 1) corresponding to the first and second non-folding regions NFA1 and NFA2 of the in-folded display apparatus DD may face each other. The rear surface of the display apparatus DD, which opposes the display surface DS (see FIG. 1) may be exposed to the outside. The display surface DS (see FIG. 1) corresponding to the folding region FA of the in-folded display apparatus DD may be folded while forming a concavely curved surface.

Referring to FIG. 2B, the folding axis FX may be defined on the rear surface of the display apparatus DD. The display apparatus DD may be out-folded around the folding axis FX. The display surface DS of the out-folded display apparatus DD may be exposed to the outside. Rear surfaces of the display apparatus DD corresponding to the first and second non-folding regions NFA1 and NFA2 may face each other. The display surface DS corresponding to the folding region FA of the out-folded display apparatus DD may be folded while forming a convexly curved surface. As the display surface DS of the out-folded display apparatus DD is exposed to the outside, the image IM may be visually recognized by a user even in a folded state.

Referring to FIG. 2A to FIG. 2C, the folding region FA has a radius of curvature R1, and may be folded at a predetermined or selected curvature. As illustrated in FIG. 2A and FIG. 2B, a distance DT between the first and second non-folding regions NFA1 and NFA2 may be substantially the same as twice the radius of curvature R1. However, the disclosure is not limited thereto, and as illustrated in FIG. 2C, the distance DT between the first and second non-folding regions NFA1 and NFA2 may be less than twice the radius of curvature R1. Accordingly, the folding region FA illustrated in FIG. 2C may be folded while having a dumbbell shape when viewed in the first direction DR1.

The display apparatus DD may operate only in one method selected from in-folding or out-folding around the folding axis FX, but is not limited thereto, and the display apparatus DD may operate such that the in-folding and the out-folding are alternately repeated. FIGS. 2A to 2C illustrate an embodiment of the display apparatus DD folded around one folding axis FX, but the disclosure is not limited thereto, and the display apparatus DD may be folded around multiple folding axes and may include multiple folding regions spaced apart from each other.

Referring to FIG. 3, the display apparatus DD-1 may be rolled around a rolling axis RX extended along the first direction DR1. The rolling axis RX may be extended in a direction parallel to long sides of the display apparatus DD-1, but is not limited thereto, and may be extended in a direction parallel to short sides of the display apparatus DD-1.

The display apparatus DD-1 may be rolled such that a display surface DS faces the outside. The display surface DS of the display apparatus DD-1 may include a display portion DA and a non-display portion NDA, and the above description may be applied with respect to the display portion DA and the non-display portion NDA. However, the disclosure is not limited thereto, and the display apparatus DD-1 may be rolled such that the display surface DS faces inward and a rear surface faces outward. The display apparatus DD-1 may be rolled and stored in a receiving member, and may be readily carried.

Referring to FIG. 4A and FIG. 4B, a display apparatus DD-2 may include a case CS in which a display opening C-OP is defined, and a display surface DS of the display apparatus DD-2 may be exposed to the outside by the display opening C-OP. The display apparatus DD-2 may include modes in which the area of the display surface DS exposed to the outside varies. FIG. 4A illustrates a perspective view of the display apparatus DD-2 operating in a first mode, and FIG. 4B illustrates a perspective view of the display apparatus DD-2 operating in a second mode.

The case CS may include a first case CS1 and a second case CS2. The first case CS1 may be coupled to the second case CS2 so as to move along a direction parallel to the first direction DR1. The first case CS1 may be coupled to the second case CS2 and move closer to the second case CS2 or away from the second case CS2.

The area of the display surface DS of the display apparatus DD-2 exposed by the display opening C-OP may be adjusted according to the movement of the first case CS1. As the first case CS1 moves away from the second case CS2, the opening area of the display opening C-OP may increase in the first direction DR1. As the opening area of the display opening C-OP increases, the area of the display surface DS exposed to the outside may also increase.

The first case CS1 is received in the second case CS2 in the display apparatus DD-2 of the first mode, so that the length of the first case CS1 in the first direction DR1 may be the smallest, and the display surface DS of the first mode may be set to the default size. The length of the first case CS1 in the first direction DR1 may be extended in the display apparatus DD-2 of the second mode, and the display surface DS of the second mode may be extended to be larger than the default size.

The first mode and the second mode of the display apparatus DD-2 may be switched according to a sliding operation of the display apparatus DD-2. A user may operate the display apparatus DD-2 from the first mode to the second mode to expand the display surface DS of the display apparatus DD-2, and may operate the display apparatus DD-2 from the second mode to the first mode to reduce the display surface DS of the display apparatus DD-2 to the default size. The user may slide the display apparatus DD-2, thereby adjusting the area of the display surface DS of the display apparatus DD-2 exposed from the case CS in various ways.

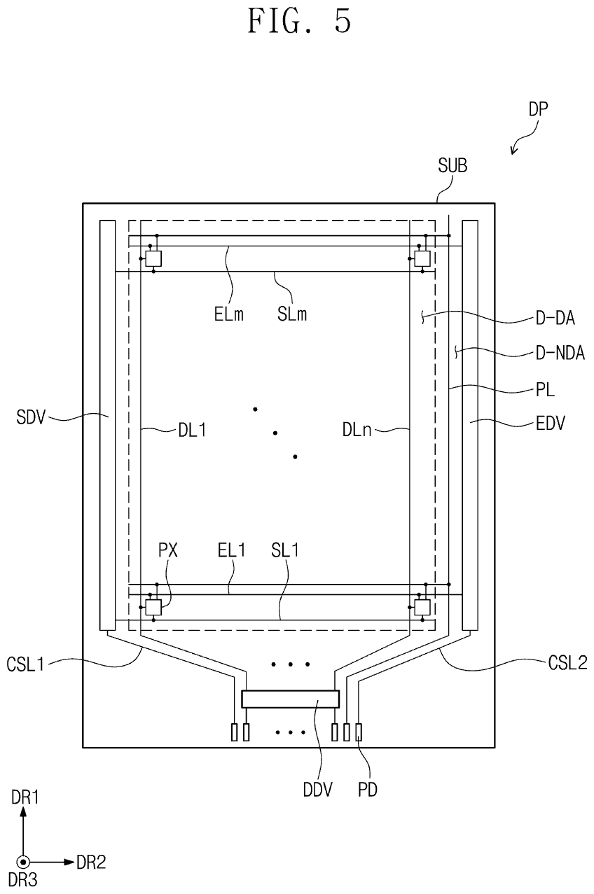

FIG. 5 is a schematic plan view of a display panel DP according to an embodiment of the disclosure.

The display panel DP may be included in the aforementioned display apparatuses DD, DD-1, and DD-2. The display panel DP may generate an image in response to an electrical signal. The display panel DP according to an embodiment may be a light emitting-type display panel, but is not particularly limited. For example, the display panel DP may be an organic light emitting display panel, an inorganic light emitting display panel, or a quantum dot light emitting display panel. A light emitting layer of the organic light emitting display panel may include an organic light emitting material, a light emitting layer of the inorganic light emitting display panel may include an inorganic light emitting material, and a light emitting layer of the quantum dot light emitting display panel may include a quantum dot, a quantum load, and the like. Hereinafter, the display panel DP will be described as the organic light emitting display panel.

Referring to FIG. 5, the display panel DP may include a base substrate SUB, pixels PX, signal lines SL1 to SLm, EL1 to ELm, DL1 to DLn, CSL1, CSL2, and PL electrically connected to the pixels PX, a scan driver SDV, a data driver DDV, and an emission driver EDV, and pads PD.

The base substrate SUB may provide a base surface on which elements and lines of the display panel DP are disposed. The base substrate SUB may include a display region D-DA and a non-display region D-NDA. The display region D-DA may be a region in which the pixels PX are disposed and display an image. The non-display region D-NDA may be a region which is disposed adjacent to the display region D-DA and in which elements and lines for driving the pixels PX are disposed and an image is not displayed. The display region D-DA may correspond to the display portion DA (see FIG. 1) of the display apparatus DD, and the non-display region D-NDA may correspond to the non-display portion NDA (see FIG. 1) of the display apparatus DD.

The pixels PX may be disposed in the display region D-DA. Each of the pixels PX may include a pixel driving circuit composed of transistors (e.g., a switching transistor, a driving transistor, etc.) and a capacitor, and a light emitting element electrically connected to the pixel driving circuit. Each of the pixels PX may emit light in response to an electrical signal applied to the pixel PX. Transistors of some pixels PX among the pixels PX may be disposed in the non-display region D-NDA, and are not limited to any one embodiment.

The scan driver SDV, the data driver DDV, and the emission driver EDV may each be disposed in the non-display region D-NDA. However, the disclosure is not limited thereto, and at least one of the scan driver SDV, the data driver DDV, and the emission driver EDV may be disposed in the display region D-DA, and as a result, the area of the non-display region D-NDA may be decreased.

The data driver DDV may be provided in the form of an integrated circuit chip, which is defined as a driving chip, and may be mounted in the non-display region D-NDA of the display panel DP. However, the disclosure is not limited thereto, and the data driver DDV may be mounted on a circuit board connected to the display panel DP and may be electrically connected to the display panel DP.

The signal lines SL1 to SLm, EL1 to ELm, DL1 to DLn, CSL1, CSL2, and PL may include scan lines SL1 to SLm, data lines DL1 to DLn, emission lines EL1 to ELm, first and second control lines CSL1 and CSL2, and a power line PL. Here, m and n are natural numbers. The pixels PX may each be electrically connected to a corresponding scan line, a corresponding data line, and a corresponding emission line among the scan lines SL1 to SLm, the data lines DL1 to DLn, and the emission lines EL1 to ELm. Depending on the configuration of the pixel driving circuit of the pixels PX, more types of signal lines may be provided in the display panel DP.

The scan lines SL1 to SLm may be extended in the second direction DR2 and may be electrically connected to the scan driver SDV. The data lines DL1 to DLn may be extended in the first direction DR1 and may be electrically connected to the data driver DDV. The emission lines EL1 to ELm may be extended in the second direction DR2 and may be electrically connected to the emission driver EDV.

The power line PL may include a portion extended in the first direction DR1 and a portion extended in the second direction DR2. The portion of the power line PL extended in the first direction DR1 and the portion thereof extended in the second direction DR2 may be disposed on different layers from each other and may be connected through a contact-hole. However, the disclosure is not limited thereto, and the portion of the power line PL extended in the first direction DR1 and the portion thereof extended in the second direction DR2 may have a shape of a single body on the same layer.

The portion of the power line PL extended in the first direction DR1 may be disposed in the non-display region D-NDA, and the portion thereof extended in the second direction DR2 may be disposed in the display region D-DA and may be electrically connected to the pixels PX. The power line PL may receive a power voltage and provide the same to the pixels PX.

The first control line CSL1 may be electrically connected to the scan driver SDV. The second control line CSL2 may be electrically connected to the emission driver EDV.

The pads PD may be disposed adjacent to a lower end of the non-display region D-NDA. The pads PD may be disposed more adjacent to a lower end of the display panel DP than the data driver DDV. The pads PD may be disposed spaced apart along the second direction DR2. The pads PD may be a portion to which a circuit board is connected, wherein the circuit board provides a signal for controlling the operation of each of the scan driver SDV, the data driver DDV, and the emission driver EDV of the display panel DP.

Each of the pads PD may be connected to a corresponding signal line among the signal lines SL1 to SLm, EL1 to ELm, DL1 to DLn, CSL1, CSL2, and PL. For example, each of the pads PD may be connected to the power line PL and the first and second control lines CSL1 and CSL2. The data lines DL1 to DLn may be connected to a corresponding PD through the data driver DDV.

The scan driver SDV may generate scan signals in response to a scan control signal. The scan signals may be applied to the pixels PX through the scan lines SL1 to SLm. The data driver DDV may generate data voltages corresponding to image signals in response to a data control signal. The data voltages may be applied to the pixels PX through the data lines DL1 to DLn. The emission driver EDV may generate emission signals in response to an emission control signal. The emission signals may be applied to the pixels PX through the emission lines EL1 to ELm.

The pixels PX may be provided with the data voltages in response to the scan signals. The pixels PX may display an image by emitting light of luminance corresponding to the data voltages in response to the emission signals. The emission duration of the pixels PX may be controlled by the emission signals. Accordingly, the display panel DP may generate an image through the display region D-DA by the pixels PX.

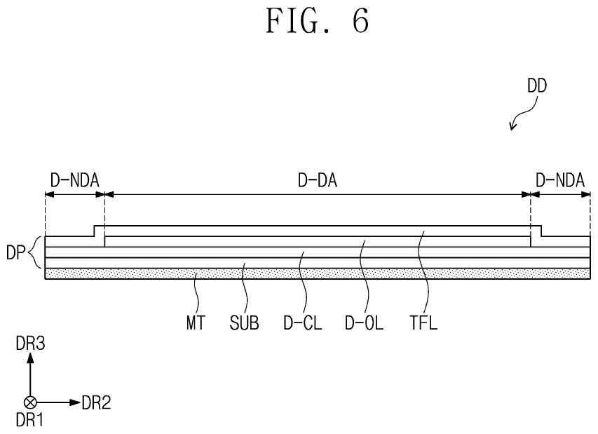

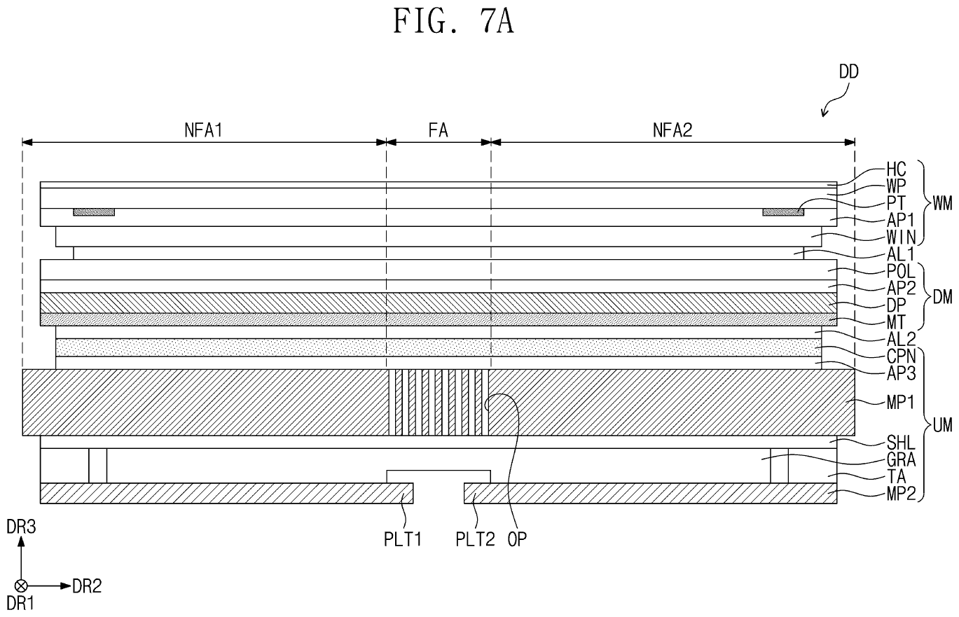

FIG. 6 is a schematic cross view of the display apparatus DD according to an embodiment of the disclosure. FIG. 6 illustrates a cross-section of each of the display panel DP and a support layer MT among components of the display apparatus DD.

Referring to FIG. 6, the display panel DP may include the base substrate SUB, a circuit layer D-CL, a display element layer D-OL, and an encapsulation layer TFL. The circuit layer D-CL, the display element layer D-OL, and the encapsulation layer TFL may be stacked on each other along the third direction DR3 on the base substrate SUB.

The base substrate SUB may include a flexible plastic substrate. For example, the base substrate SUB may include a synthetic resin layer of a single-layered or multi-layered structure. The synthetic resin layer of the base substrate SUB may include at least one of an acrylic resin, a methacrylic resin, a polyisoprene-based resin, a vinyl-based resin, an epoxy-based resin, a urethane-based resin, a cellulose-based resin, a siloxane-based resin, a polyamide-based resin, a perylene-based resin, and a polyimide-based resin. However, material of the base substrate SUB is not limited thereto.

The circuit layer D-CL may be disposed on the base substrate SUB. The circuit layer D-CL may include at least one insulation layer, driving elements (e.g., a pixel transistor), signal lines, and pads. The circuit layer D-CL may include a conductive pattern and a semiconductor pattern for forming the driving elements, the signal lines, and the pads. An insulation layer, a semiconductor layer, and a conductive layer may be formed on the base layer SUB in a coating or deposition manner, and the insulation layer, the semiconductor layer, and the conductive layer may be patterned in a photolithography manner to form the driving elements, the signal lines, and the pads.

The display element layer D-OL may be disposed on the circuit layer D-CL. The display element layer D-OL may include a light emitting element disposed overlapping the display region D-DA. The light emitting element of the display element layer D-OL may be electrically connected to the driving elements of the circuit layer D-CL, and may generate light inside the display region D-DA in response to a signal provided by the driving elements.

The light emitting element of the display element layer D-OL may include an organic light emitting element, an inorganic light emitting element, a quantum dot light emitting element, a micro-LED light emitting element, a nano-LED light emitting element, a quantum dot light emitting element, an electrophoretic element, an electro wetting element, or the like. However, the embodiment of the light emitting element is not limited to any one embodiment as long as light is generated in response to an electrical signal or the amount of light is controlled.

The encapsulation layer TFL may be disposed on the display element layer D-OL, and may encapsulate a light emitting element. The encapsulation layer TFL may include multiple thin films. The thin films of the encapsulation layer TFL may be disposed to improve optical efficiency of a light emitting element or to protect the light emitting element. In an embodiment, the encapsulation layer TFL may include at least one inorganic film and at least one organic film. The inorganic film of the encapsulation layer TFL may protect a light emitting element from moisture/oxygen. The organic film of the encapsulation layer TFL may protect a light emitting element from foreign substances such as dust particles.

The support layer MT may be disposed on a rear surface of the display panel DP. For example, the support layer MT may be disposed of a surface of the base substrate SUB of the display panel DP. The surface of the base substrate SUB on which the support layer MT is disposed may correspond to the rear surface of the display panel DP. The support layer MT may be deposited and form on a surface of the base substrate SUB, and may be coupled to the base substrate SUB without a separate adhesive layer. For example, the support layer MT may contact a surface of the base substrate SUB.

The support layer MT may be a layer having improved elastic strain and yield strength by adjusting a material to be included in the support layer MT and conditions for forming the support layer MT.

A material for forming the support layer MT may be selected in consideration of the elastic strain and yield strength required of the support layer MT. The support layer MT may include a metal material. For example, the support layer MT may include an alloy material in which two or more metal materials are mixed. In case that materials constituting a layer have crystallinity, thereby forming a grain boundary, the corresponding layer may have properties of a low elastic strain limit. However, if a layer has an amorphous structure (or amorphous phase) without a grain boundary, the layer may have properties of a relatively high elastic strain limit. Therefore, a material included in the support layer MT may be selected in consideration of whether the material has a low mixing enthalpy, and whether the material is readily amorphized, alloyed, or molded, etc.

The support layer MT may include an alloy composed of two or more materials among aluminum (Al), zirconium (Zr), titanium (Ti), molybdenum (Mo), copper (Cu), nickel (Ni), yttrium (Y), cobalt (Co), and silicon (Si). In an embodiment, the main element of the support layer MT may be determined by an element with the largest ratio of atomic percent (at %) among metal materials included in the support layer MT. Depending on the type of the main element included in the support layer MT, the physical properties of the support layer MT may vary, and the main element of the support layer MT may be selected in consideration of elastic strain and yield strength. For example, the support layer MT may include, as the main element, zirconium (Zr), aluminum (Al), titanium (Ti), and/or molybdenum (Mo). The support layer (MT) may include about 50 at % to about 90 at % or less of zirconium (Zr), aluminum (Al), titanium (Ti), and/or molybdenum (Mo).

In an embodiment, the support layer MT may include a ternary or quaternary alloy. For example, the support layer MT may include, as the main element, a ternary or quaternary alloy containing (including) zirconium (Zr), aluminum (Al), titanium (Ti), and/or molybdenum (Mo).

The support layer MT may include Zr—Cu—Co, Zr—Cu—Si, and/or Zr—Cu—Al—Ni as an alloy containing zirconium (Zr) as the main element. In the alloy containing zirconium (Zr) as the main element, the atomic percent of the zirconium (Zr) may be about 50 at % to about 90 at %. In addition to the zirconium (Zr), the atomic percent of each of the copper (Cu) and the aluminum (Al) may be about 5 at % to about 40 at %, the atomic percent of the nickel (Ni) may be about 5 at % to about 30 at %, and the atomic percent of each of the cobalt (Co) and the silicon (Si) may be about 1 at % to about 10 at %.

The support layer MT may include Al—Y—Ni—Co as an alloy containing aluminum (Al) as the main element. In the alloy containing aluminum (Al) as the main element, the atomic percent of the aluminum (Al) may be about 50 at % to about 85 at %. In addition to the aluminum (Al), the atomic percent of the nickel (Ni) may be about 5 at % to about 30 at %, and the atomic percent of each of the yttrium (Y) and the cobalt (Co) may be about 1 at % to about 10 at %.

The support layer MT may include Ti—Si—Zr—Mo as an alloy containing titanium (Ti) as the main element. In the alloy containing titanium (Ti) as the main element, the atomic percent of the titanium (Ti) may be about 50 at % to about 70 at %. In addition to the titanium (Ti), the atomic percent of the zirconium (Zr) may be about 5 at % to about 40 at %, and the atomic percent of each of the silicon (Si) and the molybdenum (Mo) may be about 1 at % to about 20 at %.

The support layer MT may include Mo—Zr—Si—Ti as an alloy containing molybdenum (Mo) as the main element. In the alloy containing molybdenum (Mo) as the main element, the atomic percent of the molybdenum (Mo) may be about 50 at % to about 70 at %. In addition to the molybdenum (Mo), the atomic percent of the zirconium (Zr) may be about 5 at % to about 40 at %, and the atomic percent of each of the silicon (Si) and the titanium (Ti) may be about 1 at % to about 20 at %.

The elastic strain and yield strength of the support layer MT may improve depending on the material of a main element included in the support layer MT, the degree of amorphization of the support layer MT, the internal structure of the support layer MT, and the like. The support layer MT may have a columnar-free structure with an increased degree of amorphization and no columnar structure, depending on process conditions for forming the support layer MT. Therefore, the support layer MT may have improved elastic strain and yield strength than a crystalline alloy having a typical grain boundary or an alloy having an amorphous phase but having a columnar structure.

The elastic strain of the support layer MT may be about 2.5% or greater. In some embodiments, the elastic strain of the support layer MT may be about 2.5% to about 4.9% or less, depending on the material of a main element included in the support layer MT. As the support layer MT has an increased degree of amorphization and a dense internal structure of a non-columnar phase, the support layer MT may have improved elastic strain compared to a typical grain-boundary alloy or an alloy having a columnar structure, both containing the same main element as the support layer MT. For example, the elastic strain of the support layer MT containing aluminum (Al) as the main element may be about 2.5% to about 2.8%, and the elastic strain of the support layer (MT) containing zirconium (Zr) as the main element may be about 4.6% to about 4.9%. As the elastic strain of the support layer MT improves, the elastic strain limit increases, so that restoration force with which the display apparatus DD returns to the original state thereof after being folded, rolled, or bent may improve.

The yield strength of the support layer MT may be about 1200 MPa or greater. In some embodiments, the yield strength of the support layer MT may be about 1200 MPa to about 2900 MPa or less, depending on the material of a main element included in the support layer MT. As the support layer MT has an increased degree of amorphization and a dense internal structure of a non-columnar phase, the support layer MT may have improved yield strength compared to a typical grain-boundary alloy or an alloy having a columnar structure, both containing the same main element as the support layer MT. For example, the yield strength of the support layer MT containing aluminum (Al) as the main element may be about 1200 MPa to about 1400 MPa or less, and the yield strength of the support layer MT containing zirconium (Zr) as the main element may be about 2700 MPa to about 2900 MPa.

The support layer MT may be thin to achieve flexibility. For example, the thickness of the support layer MT may range from several hundred nanometers (nm) to several thousand nanometers (nm). For example, the thickness of the support layer MT may be about 4000 nanometers (nm)(or about 4 micrometers (um)) or less. The support layer MT may be thin, and at the same time, may have sufficient rigidity to support the display panel DP. However, the numerical value of the thickness of the support layer MT is not limited thereto.

Depending on formation conditions of the support layer MT, the internal structure of the support layer MT may vary. The support layer MT may be formed through a deposition process, and depending on the reliability of a target layer used in the deposition process, the properties of the support layer MT may vary. For example, depending on the temperature at which the target layer is formed, the reliability of the target layer may vary, and the degree of amorphization of the support layer MT formed using the target layer may vary. In the process of depositing the support layer MT, depending on the surface temperature of a processing substrate or the power density applied to the target layer, the degree of amorphization or internal structure of the support layer MT may vary. The above will be described in detail in the description of a method for manufacturing the display apparatus DD.

As the support layer MT having a large elastic strain limit, rigidity, and restoration force is disposed below the display panel DP, the support layer MT may support the display panel DP and supplement the rigidity of the flexible display panel DP. The support layer MT may have a large elastic strain limit, rigidity, and restoration force compared to a typical polymer film. For example, the support layer MT may have elastic restoration force improved by about 160% to about 600% of the elastic restoration force of a polyimide-based film disposed below the base substrate SUB. Accordingly, the support layer MT may prevent plastic deformation (or permanent deformation) caused by stress and tensile force applied to the display apparatus DD.

Since a layer having relatively low rigidity and restoration force, such as a polymer film, has a low elastic strain limit, plastic deformation may occur due to repeated folding, rolling, or bending of a display apparatus, and deformation such as creases may be visually recognized outside the display apparatus. Accordingly, the folding reliability of the display apparatus may be degraded. Since the rigidity of a display panel is not sufficiently supplemented, cracking may occur in inner layers of the display panel.

However, since the display apparatus DD of an embodiment includes the support layer MT having a large elastic strain limit, rigidity, and restoration force, the display panel DP may be prevented from sagging or deforming by repetitive folding, rolling, or bending operations of the display apparatus DD. The support layer MT may be prevented from breaking or deforming due to stress and tensile force to cause damage to the interior of the display panel DP. As the support layer MT has flexibility, the support layer MT may be easily folded, rolled, or bent together with the display panel DP, and the folding reliability of the display apparatus DD may improve.

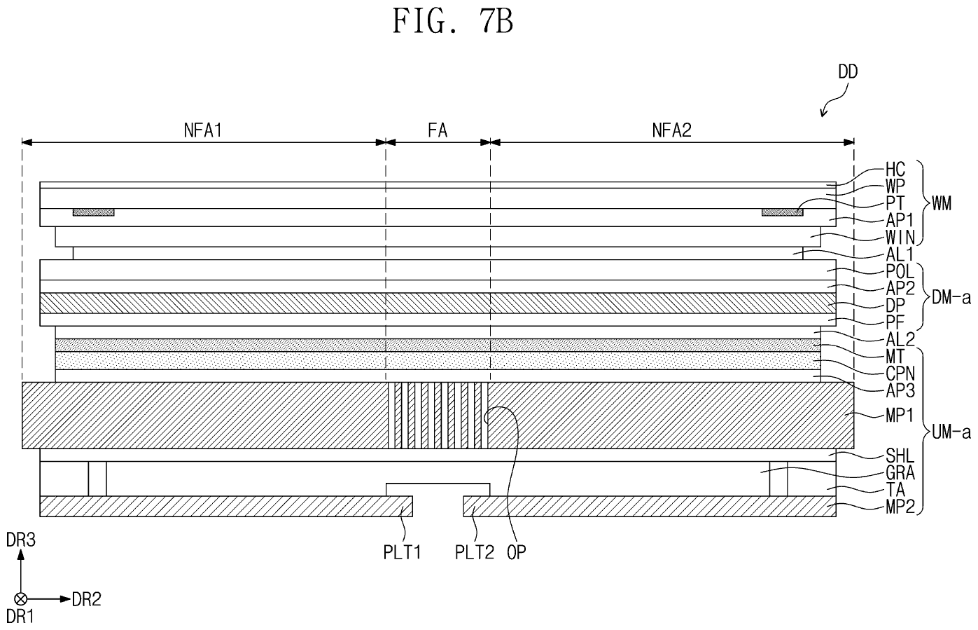

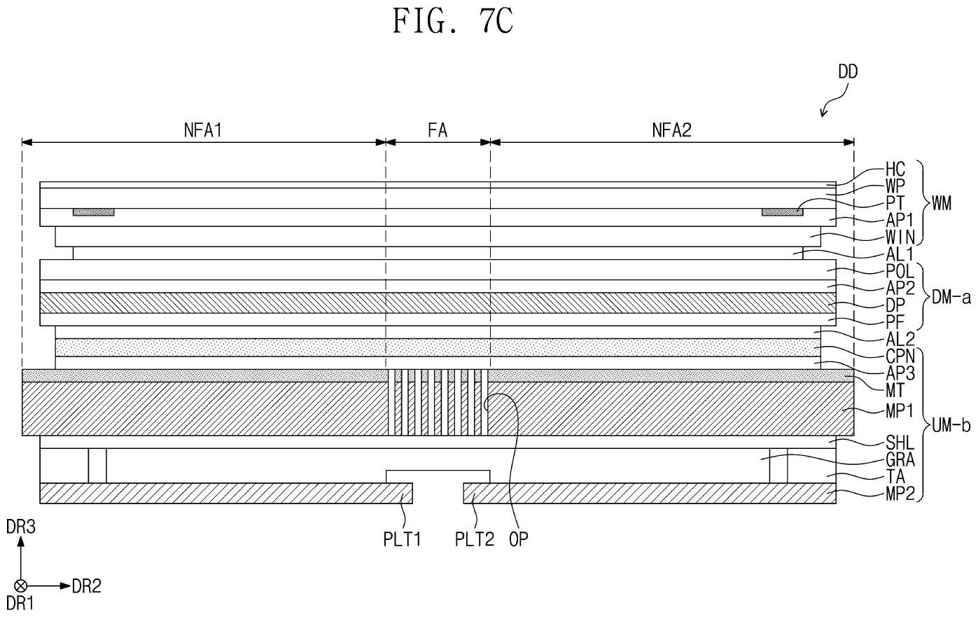

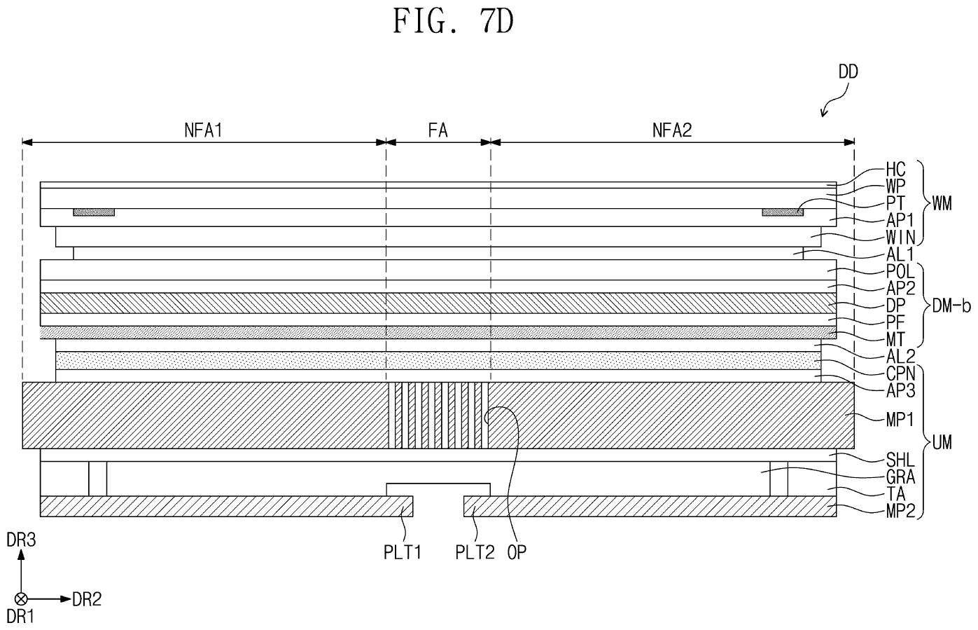

FIG. 7A to FIG. 7D are schematic cross-sectional views of the display apparatus DD according to an embodiment of the disclosure. FIG. 7A to FIG. 7D illustrate a cross-section of the display apparatus DD including additional components other than the display panel DP and the support layer MT.

Referring to FIG. 7A, the display apparatus DD may include a window module WM, a display module DM, a lower module UM, a first adhesive layer AL1, and a second adhesive layer AL2.

The first adhesive layer AL1 may be disposed between the window module WM and the display module DM to couple the window module WM and the display module DM. The second adhesive layer AL2 may be disposed between the display module DM and the lower module UM to couple the display module DM and the lower module UM. Each of the first adhesive layer AL1 and the second adhesive layer AL2 may include a transparent adhesive, such as a pressure sensitive adhesive (PSA) or an optically clear adhesive (OCA), but the type of the adhesive is not limited thereto.

The window module WM, the display module DM, and the lower module UM may include a first non-folding region NFA1, a folding region FA, and a second non-folding region NFA2. The folding regions FA of the window module WM, the display module DM, and the lower module UM may be folded around a folding axis.

The window module WM may provide the front of the display apparatus DD. For example, the front surface of the window module WM may correspond to the front surface of the display apparatus DD. The window module WM may include a window WIN, a window protection layer WP, a hard coating layer HC, a bezel pattern PT, and a first adhesive portion AP1.

The window WIN may be disposed on the display module DM. The window WIN may protect the display module DM from external impacts or scratches. The window WIN may include an optically transparent material. For example, the window WIN may include glass or a synthetic resin film.

The window WIN may have a single-layered structure or a multi-layered structure. For example, the window WIN may include multiple synthetic resin films coupled using an adhesive, or may include a glass film and a synthetic resin film coupled using an adhesive.

The window protection layer WP may be disposed on the window WIN. The first adhesive portion AP1 may be disposed between the window WIN and the window protection layer WP to couple the window WIN and the window protection layer WP. The first adhesive portion AP1 may include an optically transparent adhesive. However, the disclosure is not limited thereto, and the first adhesive portion AP1 may be omitted, and the window protection layer WP may be directly disposed on the window WIN.

The window protection layer WP may include an organic material. For example, the window protection layer WP may include at least one of polyimide, polycarbonate, polyamide, polymethylmethacrylate, polyethylene terephthalate, triacetyl cellulose, thermoplastic polyurethane (TPU), thermoset polyurethane (TSU), polyether block amide (PEBA), and a copolyester thermoplastic elastomer (COPE). However, the material of the window protection layer WP is not limited thereto.

The hard coating layer HC may be disposed on the window protection layer WP. The hard coating layer HC may be disposed on the uppermost portion of the window module layer WM. The hard coating layer HC may be directly coated and formed on an upper surface of the window protection layer WP, but is not limited thereto, and may be coupled on the window protection layer WP through a separate adhesive.

The hard coating layer HC may include a hard coating agent including at least one of an organic-based composition, an inorganic-based composition, and an organic/inorganic composite composition. For example, the hard coating layer HC may include an acrylic compound, an epoxy-based compound, a siloxane-based compound, and/or a urethane-based compound. The hard coating layer HC may improve the durability of the window module WM, prevent scratches caused by external factors, and provide a flat upper surface.

The hard coating layer HC may further include, but is not limited to, an additional functional layer such as an anti-fingerprint layer, an anti-static layer, or an anti-contamination layer, and the hard coating layer HC may be provided as a single layer and may further include functional materials such as an anti-fingerprint coating agent such as a fluorine-containing compound, an anti-reflection agent, or an anti-glare agent.

The bezel pattern PT may be disposed on a lower surface of the window protection layer WP. However, the position at which the bezel pattern PT is formed is not limited thereto, and the bezel pattern PT may be disposed on an upper surface or lower surface of the window WIN. The bezel pattern PT may be adjacent to the edge of the window protection layer WP. A region in which the bezel pattern PT is disposed may correspond to the non-display region D-NDA (see FIG. 6) of the display panel DP. The bezel pattern PT may correspond to a layer formed by coating or printing a colored material. The bezel pattern PT may prevent components of the display module DM disposed overlapping the bezel pattern PT from being visually recognized from the outside.

The display module DM may include an anti-reflection layer POL, a second adhesive portion AP2, the display panel DP, and the support layer MT. The support layer MT may be disposed on the rear surface of the display panel DP. The support layer MT may be in contact with the display panel DP. The aforementioned descriptions may be applied with respect to the display panel DP and the support layer MT.

The second adhesive layer AP2 may be disposed between the anti-reflection layer POL and the display panel DP to couple the anti-reflection layer POL and the display panel DP. The second adhesive portion AP2 may include an optically transparent adhesive. However, the disclosure is not limited thereto, and the second adhesive portion AP2 may be omitted, and the anti-reflection layer POL may be directly disposed on the display panel DP.

The anti-reflection layer POL may reduce the reflectance of external light incident on the display panel DP. In an embodiment, the anti-reflection layer POL may include a polarizing film. The polarizing film may include a phase retarder and/or a polarizer.

In an embodiment, the anti-reflection layer POL may include color filters having a predetermined or selected arrangement. For example, the color filters may be disposed corresponding to emission colors of pixels included in the display panel DP. The color filters may reduce the reflectance of external light by filtering the external light with an emission color of a corresponding pixel. The anti-reflection layer POL may further include a black matrix adjacent to the color filters.

The lower module UM may include a cover layer CPN, a third adhesive portion AP3, a first support plate MP1, a lower cover layer SHL, a heat dissipation layer GRA, and a second support plate MP2.

The cover layer CPN may be disposed below the display panel DP. The cover layer CPN may be a layer which improves resistance against compressive force caused by external pressing. Therefore, the cover layer CPN, together with the support layer MT, may prevent deformation of the display panel DP. The cover layer CPN may include a flexible material such as polyimide or polyethylene terephthalate.

The cover layer CPN may further include a colored material having low light transmittance. As a result, the cover layer CPN may absorb light incident from the outside. For example, the cover layer CPN may be a black synthetic resin film. As a result, when the display apparatus DD is viewed from an upper side of the display apparatus DD, components disposed in a lower portion of the cover layer CPN may not be visually recognized by a user.

The third adhesive portion AP3 may be disposed between the cover layer CPN and the first support plate MP1 to couple the cover layer CPN and the first support plate MP1. The third adhesive portion AP3 may include an adhesive such as a pressure sensitive adhesive or an optical clear adhesive.

The first support plate MP1 may be disposed below the cover layer CPN. The first support plate MP1 may be more rigid than the display module DM. The first support plate MP1 may support the display module DM. The first support plate MP1 may include a metal material such as stainless steel, or may include a reinforced fiber composite such as carbon fiber or glass fiber.

The first support plate MP1 may have openings OP corresponding to the folding region FA. The openings OP may be defined by penetrating the first support plate MP1. A portion of the first support plate MP1 overlapping the folding region FA by the openings OP may have improved flexibility. Accordingly, the first support plate MP1 may be easily folded together with the window module WM and the display module DM around the folding region FA.

The lower cover layer SHL may be disposed below the first support plate MP1. The lower cover layer SHL may cover the openings OP defined in the first support plate MP1. The lower cover layer SHL may prevent foreign substances from entering the display module DM through the openings OP below the display module DM.

The lower cover layer SHL may have a lower elastic modulus than the first support plate MP1. For example, the lower cover layer SHL may include thermoplastic polyurethane or rubber. However, the material of the lower cover layer SHL is not limited thereto. The lower cover layer SHL may be manufactured in the form of a sheet and be attached to the first support plate MP1.

The heat dissipation layer GRA may be disposed between the first support plate MP1 and the second support plate MP2. The heat dissipation layer GRA may have heat dissipation properties. For example, the heat dissipation layer GRA may include graphite. However, the material of the heat dissipation layer GRA is not limited thereto. The heat dissipation layer GRA may dissipate heat generated from electronic elements disposed in a lower portion of the display panel DP, or dissipate heat transmitted from the display panel DP.

The heat dissipation layer GRA may further include a foam sheet having elastic force. As a result, the heat dissipation layer GRA may have not only a heat dissipation function but also a function of protecting the display module DM by absorbing external impacts.

A step compensator TA and the heat dissipation layer GRA may be disposed on the same layer. The step compensator TA may be disposed between the first support plate MP1 and the second support plate MP2. The step compensator TA may be disposed on the outer periphery of the heat dissipation layer GRA. The step compensator TA may be provided in the form of a double-sided tape or an insulation film. In an embodiment, the step compensator TA may include a waterproof tape. In an embodiment, the step compensator TA may be provided by being attached to a set bracket of display apparatus DD.

The second support plate MP2 may be disposed below the heat dissipation layer GRA. The second support plate MP2 may be more rigid than the display module DM. For example, the second support plate MP2 may include a metal material such as stainless steel. However, the material of the second support plate MP2 is not limited thereto.

The second support plate MP2 may include first and second plates PLT1 and PLT2 spaced apart in the second direction DR2. The first plate PLT1 may be disposed overlapping the first non-folding region NFA1, and the second plate PLT2 may be disposed overlapping the second non-folding region NFA2. As the first and second plates PLT1 and PLT2 are spaced apart corresponding the folding region FA, in case that the display apparatus DD is folded, stress or tensile force may not be applied to the second support plate MP2 corresponding to the folding region FA. Accordingly, the second support plate MP2 may be easily folded together with the window module WM and the display module DM around the folding region FA.

However, the stacking structure of the window module WM, the display module DM, and the lower module UM illustrated in FIG. 7A is only an example, and without being limited thereto, and the display apparatus DD may further include additional components or some of the components of the display apparatus DD illustrated in FIG. 7A may be omitted. The stacking order of the components included in the display apparatus DD is not limited to the illustrated embodiment.

Referring to FIG. 7B and FIG. 7C, the stacking position of the support layer MT inside the display apparatus DD may change. For example, the support layer MT may be disposed inside lower modules UM-a and UM-b.

Referring to FIG. 7B, inside the lower module UM-a, the support layer MT may be disposed on a cover layer CPN. The support layer MT may be deposited on an upper surface of the cover layer CPN and disposed in contact with the cover layer CPN. However, the disclosure is not limited thereto, and the support layer MT may be disposed on a lower surface of the cover layer CPN or on both surfaces of the cover layer CPN corresponding to the upper surface and the lower surface.

Referring to FIG. 7C, inside the lower module UM-b, the support layer MT may be disposed on a first support plate MP1. The support layer MT may be deposited on an upper surface of the first support plate MP1 and disposed in contact with the first support plate MP1. However, the disclosure is not limited thereto, and the support layer MT may be disposed on a lower surface of the first support plate MP1 or on both surfaces of the first support plate MP1 corresponding to the upper surface and the lower surface.

Openings OP may be defined by penetrating not only the first support plate MP1, but also the support layer MT. Accordingly, the flexibility of a portion of the support layer MT corresponding to the folding region FA may improve. However, the disclosure is not limited thereto, and the support layer MT may be disposed on the upper surface of the first support plate MP1 to cover the openings OP.

Referring to FIG. 7B and FIG. 7C, a display module DM-a may further include a protection film PF disposed on a rear surface of a display panel DP. The protection film PF may be coupled on the rear surface of the display panel DP using an adhesive.

The protection film PF may prevent damage to the display panel DP caused by an external impact applied to a lower portion of the display panel DP. The protection film PF may prevent scratches from being generated on the rear surface of the display panel DP during a manufacturing process of the display panel DP. The protection film PF may include a synthetic resin film. For example, the synthetic resin film may include at least one of polyimide and polyethylene terephthalate. However, the material of the protection film PF is not limited thereto.

Referring to FIG. 7D, the support layer MT may be disposed inside a display module DM-b. The support layer MT may be disposed on a surface of the protection film PF. For example, the support layer MT may be deposited on a rear surface of the protection film PF and disposed in contact with the protection film PF. However, the disclosure is not limited thereto, and the support layer MT may be disposed on a front of the protection film PF or on both surfaces of the protection film PF corresponding to the front surface and the rear surface.

The stacking position of the support layer MT inside the display apparatus DD is not limited as long as the support layer MT is disposed in a lower portion of the display panel DP.

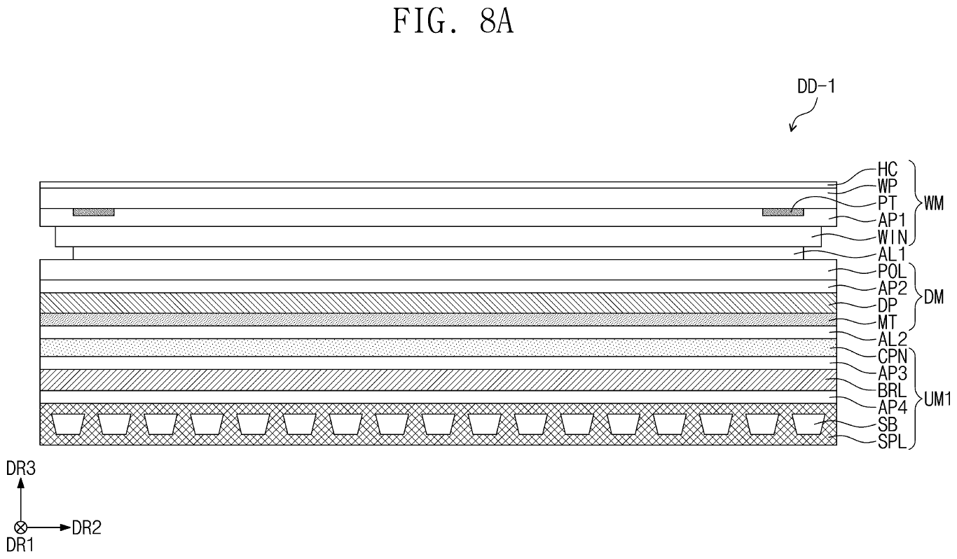

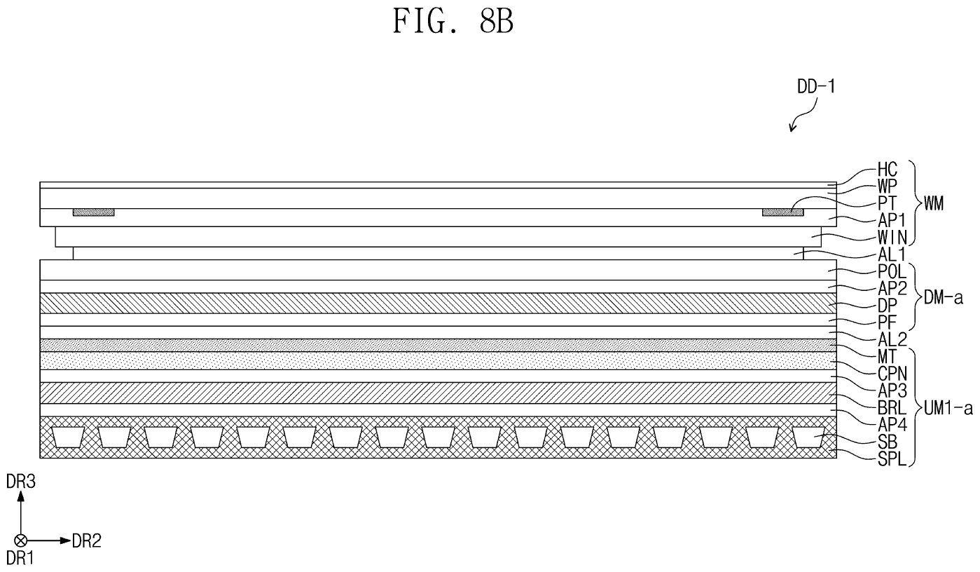

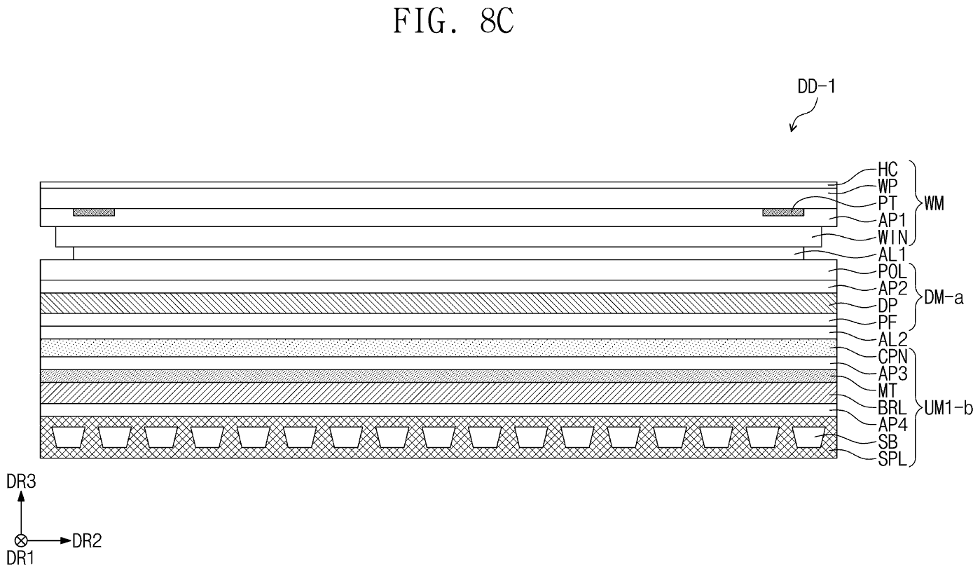

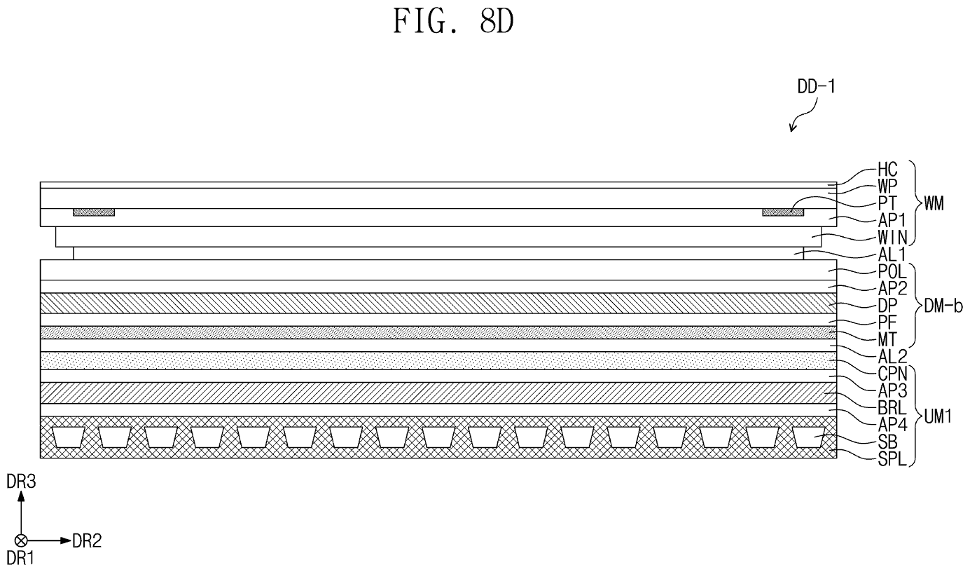

FIG. 8A to FIG. 8D are schematic cross-sectional views of the display apparatus DD-1 according to an embodiment of the disclosure. As described above, the display apparatus DD-1 illustrated in FIG. 8A to FIG. 8D may be rolled around the rolling axis RX (see FIG. 3) extended along the first direction DR1.

Referring to FIG. 8A, the display apparatus DD-1 may include a window module WM, a display module DM, a lower module UM1, a first adhesive layer AL1, and a second adhesive layer AL2. The aforementioned descriptions may be applied with respect to the window module WM, the display module DM, the first adhesive layer AL1, and the second adhesive layer AL2, and hereinafter, the descriptions thereof will be omitted. There are some differences between the display apparatus DD-1 of FIG. 8A and the display apparatus DD of FIG. 7A in the configuration of the lower module UM1.

Referring to FIG. 8A, the lower module UM1 may include a cover layer CPN, a third adhesive portion AP3, a barrier layer BRL, a fourth adhesive portion AP4, a support base portion SPL, and support bars SB. The above description may be applied with respect to the cover layer CPN of FIG. 8A, and hereinafter, the description thereof will be omitted.

The third adhesive portion AP3 may be disposed between the cover layer CPN and the barrier layer BRL to couple the cover layer CPN and the barrier layer BRL. The fourth adhesive portion AP4 may be disposed between the barrier layer BRL and the support base portion SPL to couple the barrier layer BRL and the support base portion SPL. The third adhesive portion AP3 and the fourth adhesive portion AP4 may include an adhesive such as a pressure sensitive adhesive or an optical clear adhesive. At least one of the third adhesive portion AP3 and the fourth adhesive portion AP4 may be omitted.

The barrier layer BRL, together with the cover layer CPN and the support layer MT, may be a layer which prevents deformation of the display panel DP. For example, the barrier layer BRL may include a flexible material such as polyimide or polyethylene terephthalate.

However, the disclosure is not limited thereto, and the barrier layer BRL may be a layer which absorbs an external impact. The barrier layer BRL may have a porous structure. For example, the barrier layer BRL may include an acrylonitrile butadiene styrene copolymer, polyurethane, polyethylene, ethylene vinyl acetate, or a synthetic resin foam such as polyvinyl chloride. However, the disclosure is not limited thereto, the barrier layer BRL may be omitted.

The support bars SB may be disposed inside the support base portion SPL. Each of the support bars SB may be extended along an extension direction of the rolling axis RX (see FIG. 3). The support bars SB may be arranged along a direction which intersects an extension direction of the support bars SB. For example, the support bars SB are extended along the first direction DR1, and may be arranged along the second direction DR2 inside the support base portion SPL.

The support bars SB may have a trapezoidal shape on a cross-section. However, the disclosure is not limited thereto, and the support bars SB may have various shapes, such as a circular shape, an oval shape, a triangular shape, a quadrangular shape, a rhombic shape, or the like on a cross-section.

The support base portion SPL may cover the support bars SB. The support base portion SPL may come into contact with the support bars SB. The support base portion SPL in a single body shape may cover an upper surface and a lower surface of each of the support bars SB. The support base portion SPL may be filled between the support bars SB spaced apart along the second direction DR2, and the support base portion SPL may connect the support bars SB.

The modulus of the support bars SB may be larger than the modulus of the support base portion SPL. The support bars SB may include a material having greater rigidity than the support base portion SPL, and may support the display module DM. The support bars SB may improve impact resistance of the lower module UM1. For example, the support bars SB may include a metal such as aluminum, stainless steel, or invar, or may include carbon fiber. However, the material of the support bars SB is not limited thereto.

The support base portion SPL may include a material which is more flexible than the support bars SB. The support base portion SPL connects the support bars SB, and allows the lower module UM1 to be easily rolled at a predetermined or selected curvature. The support base portion SPL covers the support bars SB, and may provide a flat upper surface to the display module DM. Accordingly, the support base portion SPL may improve surface quality of the display module DM.

However, the stacking structure of the window module WM, the display module DM, and the lower module UM1 illustrated in FIG. 8A is only an example, and without being limited thereto, and the display apparatus DD-1 may further include additional components or some of the components of the display apparatus DD-1 illustrated in FIG. 8A may be omitted. The stacking order of the components included in the display apparatus DD-1 is not limited to the illustrated embodiment.

Referring to FIG. 8B and FIG. 8C, the stacking position of the support layer MT inside the display apparatus DD-1 may change. For example, the support layer MT may be disposed inside lower modules UM1-a and UM1-b.

Referring to FIG. 8B, inside the lower module UM1-a, the support layer MT may be disposed on a cover layer CPN. The support layer MT may be deposited on an upper surface of the cover layer CPN and disposed in contact with the cover layer CPN. However, the disclosure is not limited thereto, and the support layer MT may be disposed on a lower surface of the cover layer CPN or on both surfaces of the cover layer CPN corresponding to the upper surface and the lower surface.

Referring to FIG. 8C, inside the lower module UM1-b, the support layer MT may be disposed on a barrier layer BRL. The support layer MT may be deposited on an upper surface of the barrier layer BRL and disposed in contact with the barrier layer BRL. However, the disclosure is not limited thereto, and the support layer MT may be disposed on a lower surface of the barrier layer BRL or on both surfaces of the barrier layer BRL corresponding to the upper surface and the lower surface.

Referring to FIG. 8B and FIG. 8C, a display module DM-a may further include a protection film PF disposed on a rear surface of a display panel DP. The description of the display module DM-a of FIG. 7B may be applied to the display module DM-a of FIG. 8B and FIG. 8C.

Referring to FIG. 8D, the support layer MT may be disposed on a surface of the protection film PF. For example, the support layer MT may be deposited on a rear surface of the protection film PF and disposed in contact with the protection film PF. However, the disclosure is not limited thereto, and the support layer MT may be disposed on a front of the protection film PF or on both surfaces of the protection film PF corresponding to the front surface and the rear surface.

The stacking position of the support layer MT inside the display apparatus DD-1 is not limited as long as the support layer MT is disposed in a lower portion of the display panel DP.

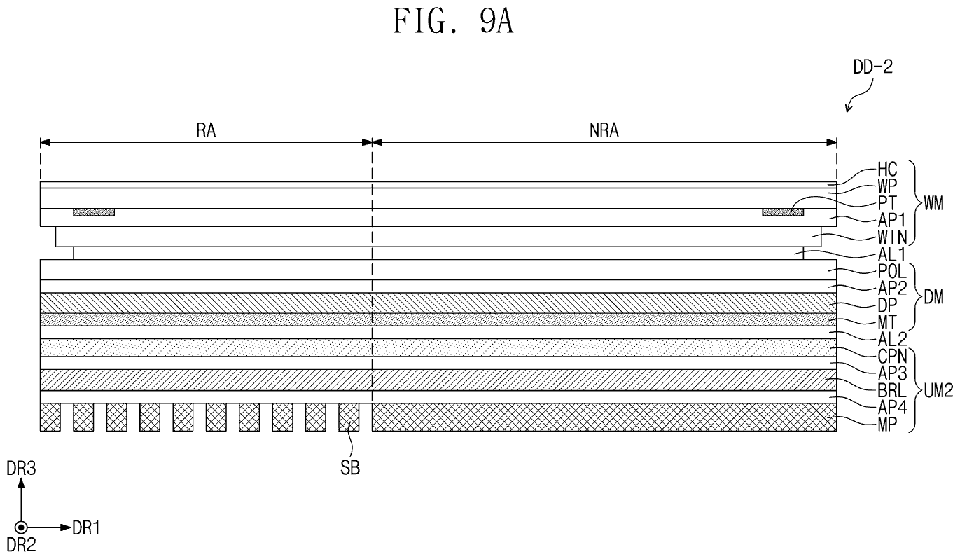

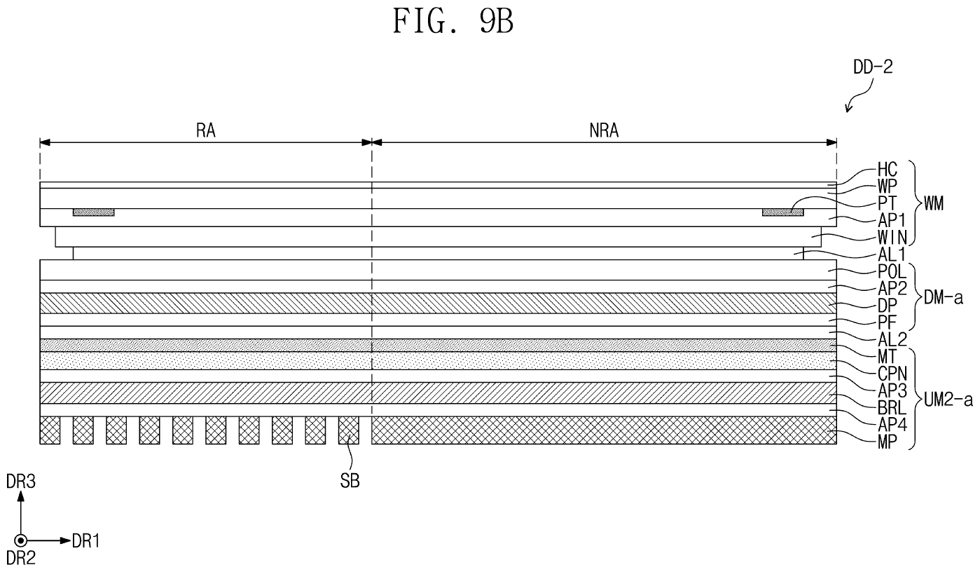

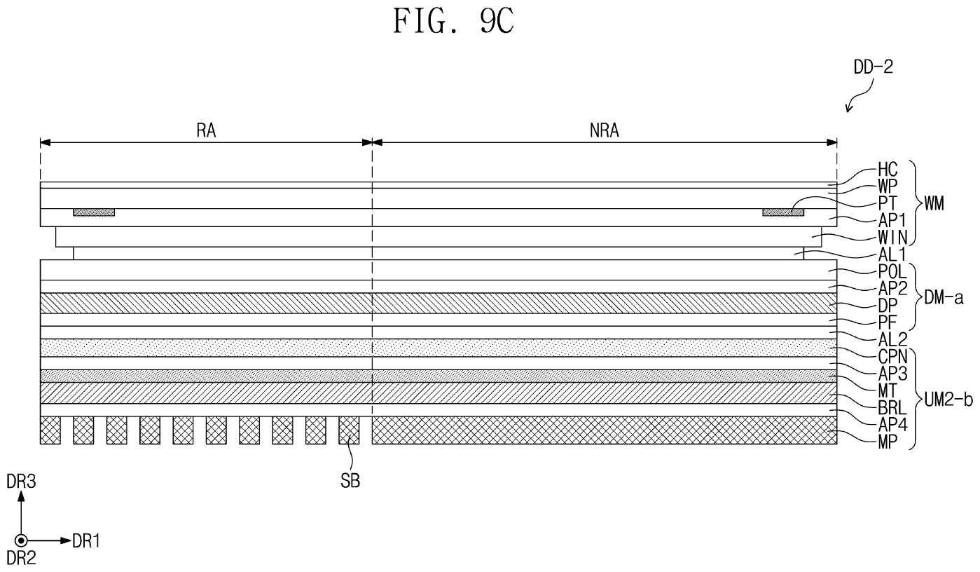

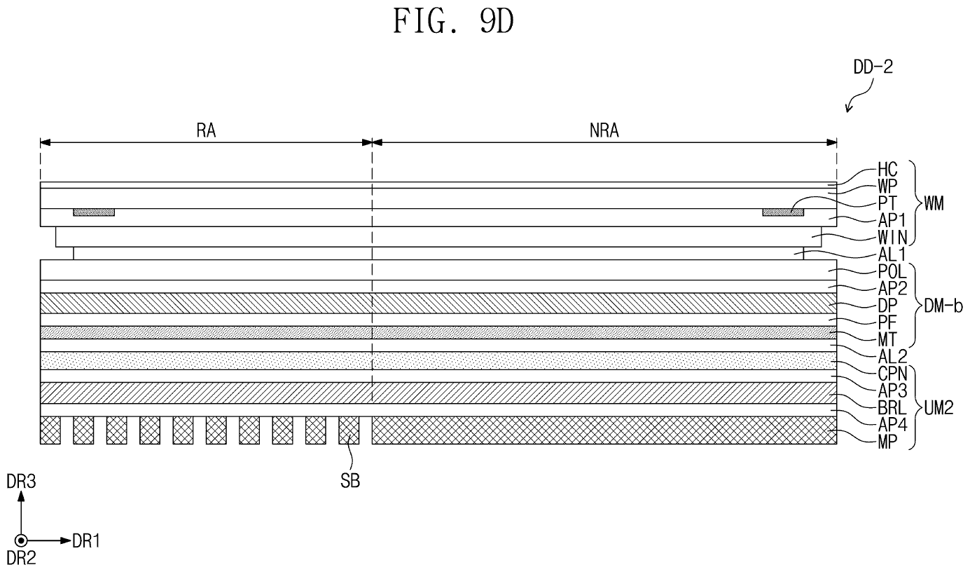

FIG. 9A to FIG. 9D are schematic cross-sectional views of the display apparatus DD-2 according to an embodiment of the disclosure. The display apparatus DD-2 illustrated in FIG. 9A to FIG. 9D may be a slidable display apparatus as illustrated in FIG. 4A and FIG. 4B.

Referring to FIG. 9A, the display apparatus DD-2 may include a rolling region RA and a flat region NRA adjacent to the rolling region RA. The rolling region RA may be a region which is rolled around a rolling axis extended in the second direction DR2. The rolling region RA may be a region which is disposed inside the aforementioned case CS (see FIG. 4A) and which is wound and unwound on a roller according to the operation of the case CS. The flat region NRA may be a region which provides a default size of the display surface DS (see FIG. 4A) and which remains flat.

The display apparatus DD-2 may include a window module WM, a display module DM, a lower module UM2, a first adhesive layer AL1, and a second adhesive layer AL2. The aforementioned descriptions may be applied with respect to the window module WM, the display module DM, the first adhesive layer AL1, and the second adhesive layer AL2, and hereinafter, the descriptions thereof will be omitted. There are some differences between the display apparatus DD-2 of FIG. 9A and the display apparatus DD-1 of FIG. 8A in the configuration of the lower module UM2.

Referring to FIG. 9A, the lower module UM2 may include a cover layer CPN, a third adhesive portion AP3, a barrier layer BRL, a fourth adhesive portion AP4, a support plate MP, and support bars SB. The aforementioned description may be applied with respect to the cover layer CPN, the third adhesive portion AP3, and the barrier layer BRL, and hereinafter, the descriptions thereof will be omitted.

The fourth adhesive portion AP4 may be disposed between the barrier layer BRL and the support plate MP and between the barrier layer BRL and the support bars SB to couple the barrier layer BRL and the support plate MP, and to couple the barrier layer BRL and the support bars SB.

The support bars SB may be disposed below the barrier layer BRL corresponding to the rolling region RA. Each of the support bars SB may be extended along an extension direction of a rolling axis. The support bars SB may be arranged along a direction which intersects an extension direction of the support bars SB. For example, the support bars SB are extended along the second direction DR2, and may be arranged along the first direction DR1.

The support bars SB may include a metal having a predetermined or selected rigidity. For example, the support bars SB may include a metal such as aluminum, stainless steel, or invar, or may include carbon fiber. However, as long as the support bars SB are provided as segments and support the display module DM corresponding to the rolling region RA, the material of the support bars SB is not limited thereto.

The support plate MP may be disposed below the barrier layer BRL corresponding to the flat region NRA. The support plate MP may have a plate shape parallel to the first direction DR1 and the second direction DR2. The support plate MP and the support bars SB may be disposed on the same layer, but are not limited thereto.

The support plate MP may include a material having rigidity. For example, the support plate MP may include stainless steel, aluminum, or an alloy thereof. However, the material of the support plate MP is not limited thereto. The support plate MP may support the display module DM such that the flat region NRA of the display module DM remains flat in the first mode and the second mode of the display apparatus DD-2. The support plate MP may improve impact resistance of the lower module UM2.

Referring to FIG. 9B and FIG. 9C, the stacking position of the support layer MT inside the display apparatus DD-2 may change. For example, the support layer MT may be disposed inside lower modules UM2-a and UM2-b.

Referring to FIG. 9B, inside the lower module UM2-a, the support layer MT may be disposed on a cover layer CPN. The support layer MT may be deposited on an upper surface of the cover layer CPN and disposed in contact with the cover layer CPN. However, the disclosure is not limited thereto, and the support layer MT may be disposed on a lower surface of the cover layer CPN or on both surfaces of the cover layer CPN corresponding to the upper surface and the lower surface.

Referring to FIG. 9C, inside the lower module UM2-b, the support layer MT may be disposed on a barrier layer BRL. The support layer MT may be deposited on an upper surface of the barrier layer BRL and disposed in contact with the barrier layer BRL. However, the disclosure is not limited thereto, and the support layer MT may be disposed on a lower surface of the barrier layer BRL or on both surfaces of the barrier layer BRL corresponding to the upper surface and the lower surface.

Referring to FIG. 9B and FIG. 9C, a display module DM-a may further include a protection film PF disposed on a rear surface of a display panel DP. The description of the display module DM-a of FIG. 7B may be applied to the display module DM-a of FIG. 9B and FIG. 9C.

Referring to FIG. 9D, the support layer MT may be disposed on a surface of the protection film PF. For example, the support layer MT may be deposited on a rear surface of the protection film PF and disposed in contact with the protection film PF. However, the disclosure is not limited thereto, and the support layer MT may be disposed on a front of the protection film PF or on both surfaces of the protection film PF corresponding to the front surface and the rear surface.

The stacking position of the support layer MT inside the display apparatus DD-2 is not limited as long as the support layer MT is disposed in a lower portion of the display panel DP.

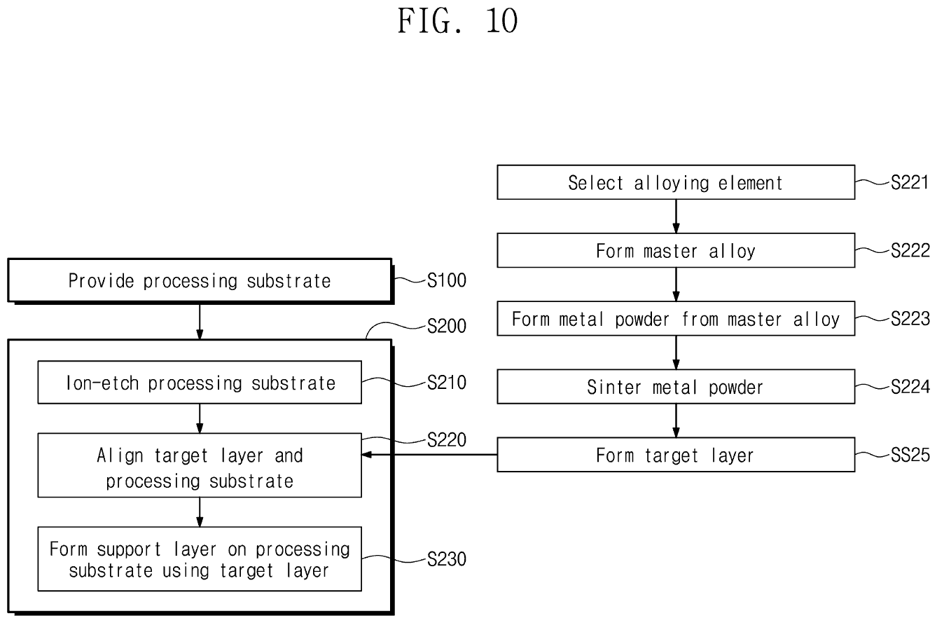

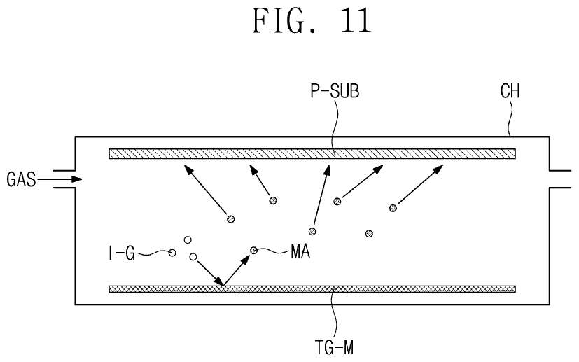

FIG. 10 is a flowchart of a method for manufacturing a display apparatus according to an embodiment of the disclosure. FIG. 11 is a schematic cross-sectional view illustrating a step of forming a support layer according to an embodiment of the disclosure. FIG. 6 may correspond to a cross-section of the display apparatus DD manufactured by the manufacturing method according to an embodiment of the disclosure. Hereinafter, referring to FIG. 6, FIG. 10, and FIG. 11 together, the method for manufacturing a display apparatus according to an embodiment will be described.

The method for manufacturing a display apparatus according to an embodiment of the disclosure may include providing a process substrate including a display panel S100 and forming a support layer on the processing substrate S200.

In an embodiment, a processing substrate P-SUB may be a target on which a support layer MT is formed. For example, the processing substrate P-SUB may include a display panel DP. The display panel DP included in the processing substrate P-SUB may be formed by stacking, on a carrier substrate, a base substrate SUB, a circuit layer D-CL, a display element layer D-OL, and an encapsulation layer TFL. For example, the base substrate SUB, the circuit layer D-CL, the display element layer D-OL, and the encapsulation layer TFL of the display panel DP may be formed through performing a photolithography process multiple times and performing an etching process multiple times. The carrier substrate may be removed in a step of forming a support layer MT.

The step of forming the support layer MT S200 may include ion-etching the provided processing substrate P-SUB S210, providing a target layer TG-M to align the target layer TG-M and the processing substrate P-SUB S220, and forming the support layer MT on the processing substrate P-SUB using the target layer TG-M S230.

The ion-etching may be performed on a processing surface of the processing substrate P-SUB on which the support layer MT is deposited. For example, the processing surface of the processing substrate P-SUB may correspond to a surface of the base substrate SUB of the display panel DP. Through the ion-etching, irregularities may be formed on the processing surface, and thus, interfacial adhesive force between the supported layer MT to be deposited later and the processing surface may improve. Accordingly, the support layer MT may be prevented from being peeled off from the processing substrate P-SUB.

The target layer TG-M may be prepared in a separate process and be provided in a chamber CH. A manufacturing step of the target layer TG-M for providing the target layer TG-M may include selecting an alloying element S221, forming a master alloy S222, forming metal powder from the master alloy S223, sintering the metal powder S224, and forming a target layer S225.

In the selecting of an alloying element, the alloying element may be selected in consideration of whether the alloying element can be easily amorphized, whether the alloying element can be easily molded or processed, whether the alloying element has a low mixing enthalpy, and the atomic radius of the alloying element, etc. A material included in the target layer TG-M may vary depending on a material of the support layer MT to be formed. For example, the target layer TG-M may include an alloy composed of two or more materials among aluminum (Al), zirconium (Zr), titanium (Ti), molybdenum (Mo), copper (Cu), nickel (Ni), yttrium (Y), cobalt (Co), and silicon (Si). Among the above, the main element of the target layer TG_M may include zirconium (Zr), aluminum (Al), titanium (Ti), and/or molybdenum (Mo). The description of the atomic percent of the support layer MT may be applied to the atomic percent of the alloying element included in the target layer TG-M.

Metal materials selected as the alloying elements may be melted in a vacuum state to prepare the master alloy, and the metal powder containing the alloying elements may be prepared from the master alloy. The metal powder may be prepared to have a particle size corresponding to about 30 micrometers (um) to about 50 micrometers (um). However, the disclosure is not limited thereto.

The metal powder may be sintered. Sintering is a process in which metal powder is formed into an agglomerated mass through a thermal activation process. For example, in the sintering process, the metal powder may be adhered to each other and solidified in order to be in a thermodynamically stable state. After the metal powder is sintered, the sintered body may be cut or ground to finally form the target layer TG-M.

The sintering may affect the size, particle distribution, particle structure, degree of agglomeration, and the like of particles inside the target layer TG-M to be finally formed. Among the above, there is a sintering temperature as a factor affecting the properties of the target layer TG-M. In an embodiment, the sintering may be performed under conditions for minimizing recrystallization and forming a stably amorphized support layer MT. For example, the sintering may be performed in a temperature range of equal to or higher than the glass transition temperature of an alloying element to be sintered to equal to or lower than the crystallization temperature thereof. Therefore, depending on a main element of the metal powder, the range of sintering temperatures may vary.

The target layer TG-M and the processing substrate P-SUB may be provided and aligned in the chamber CH. The target layer TG-M and the processing surface of the processing substrate P-SUB may face each other. The target layer TG-M may be a layer including a material to be deposited on the processing substrate P-SUB, and the processing substrate P-SUB may be an object on which a film is deposited. To facilitate the deposition process, the inside of the chamber CH may be provided in a vacuum state. An inert gas such as argon (Ar) may be introduced into the chamber CH.

An electric field may be applied to each of the target layer TG-M and the processing substrate P-SUB. For example, a negative electrode may be applied to the target layer TG-M corresponding to a material to be deposited, and a positive electrode may be applied to the processing substrate P-SUB. An electric field may be formed between the processing substrate P-SUB and the target layer TG-M, and the inert gas may be ionized to form an ion gas I-G. For example, the ion gas I-G may be an argon cation (Ar⁺).

As the surface of the target layer TG-M to which the negative electrode is applied maintains a negative potential, the ion gas I-G may collide with a surface of the target layer TG-M. A source particle MA may be emitted from the surface of the target layer TG-M by the collision of the ion gas I-G, and the source particle MA may be deposited on the processing surface of the processing substrate P-SUB. The source particle MA may be deposited in the form of a film on the processing surface of the processing substrate P-SUB to form the support layer MT.

In a sputtering process, depending on the deposition process environment or conditions, the particle structure, particle distribution, and the like of the support layer MT deposited on the processing substrate P-SUB may vary. The support layer MT has an amorphous structure, and thus, may have a high elastic limit. Even if the support layer MT has an amorphous structure, in case that there is a columnar structure formed inside the layer, the elastic strain and strength may be degraded. For example, in case that the support layer MT has no columnar structure, that is, a columnar-free dense amorphous structure, the elastic strain and strength may improve. By controlling the sputtering deposition process environment or conditions, it is possible to form a support layer MT with a minimized columnar structure and with an amorphous structure.

In the sputtering process, the particle structure of the support layer MT may vary depending on a method for applying power. For example, sputtering deposition may be performed through a high-frequency pulsed-DC power supply device. In order to improve the ionization rate of the source particle MA, the deposition may be performed using a magnetron sputtering device with a magnet added to a lower portion of the target layer TG-M. Accordingly, the support layer MT may have a dense amorphous structure, and the support layer MT having high elastic strain and strength may be formed.

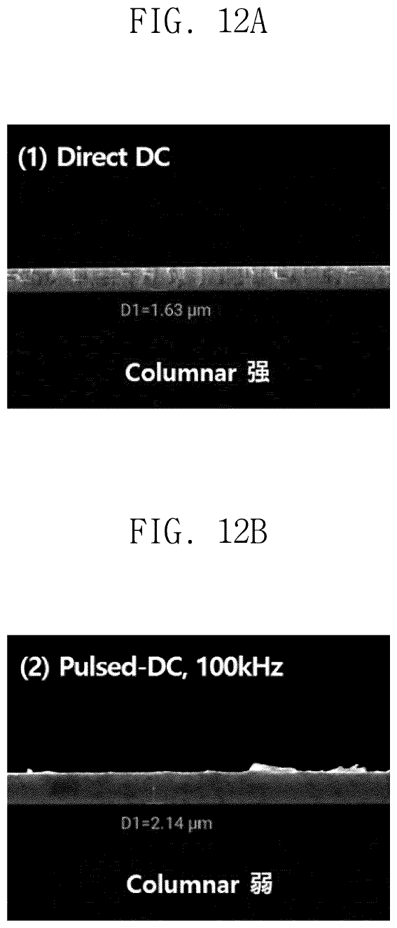

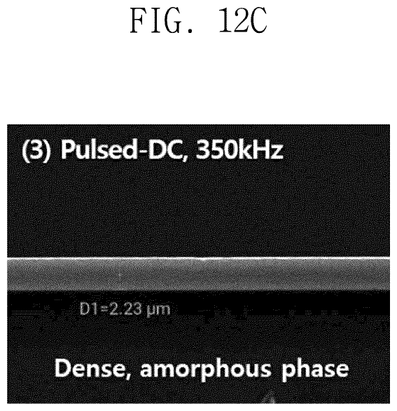

FIG. 12A to FIG. 12C are schematic cross-sectional structural images of the support layer MT according to power application methods and frequencies. FIG. 12A is a cross-sectional structure of a support layer sputtering-deposited through a DC power supply device. FIG. 12B and FIG. 12C are cross-sectional structures of a support layer sputtering-deposited through a high-frequency pulsed-DC power supply device. FIG. 12B is an image of a support layer deposited under a 100 kHz condition, and FIG. 12C is an image of a support layer deposited under a 350 kHz condition.

Referring to FIG. 12A to FIG. 12C, the support layer sputtering-deposited through the DC power supply device may have a columnar structure. However, the support layer sputtering-deposited through the high-frequency pulsed-DC power supply device may have a minimized columnar structure. In case that sputtering-deposition is performed by applying power under relatively high frequency conditions, the support layer MT may have a dense amorphous structure without a columnar structure.

In the sputtering process, the particle structure of the support layer MT may vary depending on the density (power density) at which power is applied to the target layer TG-M. As the power density increases, the deposition rate may increase. As the power density increases, the surface temperature of the processing substrate P-SUB may also increase.

However, in case that the surface temperature of the processing substrate P-SUB increases, the support layer MT deposited on the processing substrate P-SUB may be recrystallized. In case that the support layer MT is recrystallized, the elastic strain limit and strength of the support layer MT may be lowered, so the support layer MT may be required to be formed under conditions that minimize the recrystallization. However, in case that the power density is too low, the support layer MT may be insufficiently deposited, and the deposition rate may decrease. Therefore, it may be necessary to apply a power density in an appropriate range to the target layer TG-M. For example, in the sputtering process, the power density may be about 4 W/cm² to about 5 W/cm².

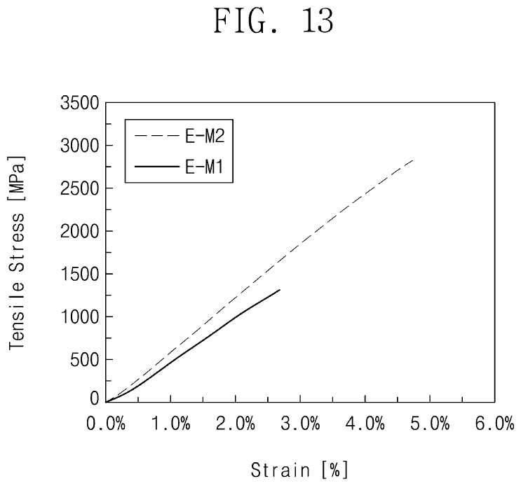

FIG. 13 is a schematic graph of tensile stress according to the strain of example embodiments E-M1 and E-M2. Referring to FIG. 13, a first embodiment E-M1 may correspond to a support layer MT containing aluminum (Al) as the main element, and a second embodiment E-M1 may correspond to a support layer MT containing zirconium (Zr) as the main element.

The first embodiment E-M1 may include an Al—Y—Ni—Co alloy. In the alloy included in the first embodiment E-M1, the atomic percent of aluminum (Al) may correspond to about 85.4 at %, the atomic percent of yttrium (Y) may correspond to about 7.8 at %, the atomic percent of nickel (Ni) may correspond to about 4.9 at %, and the atomic percent of cobalt (Co) may correspond to about 1.9 at %.

The second embodiment E-M2 may include a Zr—Cu—Co alloy. In the alloy included in the second embodiment E-M2, the atomic percent of zirconium (Zr) may correspond to about 73.7 at %, the atomic percent of copper (Cu) may correspond to about 18.5 at %, and the atomic percent of cobalt (Co) may correspond to about 7.8 at %.

The first embodiment E-M1 and the second embodiment E-M2 may be prepared to have a thickness in the range of about 2.0 micrometers (um) to about 3.5 micrometers (um).

The first embodiment E-M1 and the second embodiment E-M2 may be prepared to have an amorphous structure with a minimized columnar structure by controlling the temperature at which the first embodiment E-M1 and the second embodiment E-M2 are deposited. The first embodiment E-M1 and the second embodiment E-M2 may be prepared by sputtering a target layer on a substrate. The starting temperature (or atmosphere temperature) of the sputtering process for preparing the first embodiment E-M1 and the second embodiment E-M2 may correspond to room temperature, and the power density may be controlled to about 4.3 W/cm² such that the deposition temperature is not raised to a temperature equal to or higher than the temperature at which the recrystallization occurs during the sputtering process.

Accordingly, the first embodiment E-M1 and the second embodiment E-M2 may be prevented from being recrystallized, and may have an amorphous structure with a minimized columnar structure. As a result, the first and second embodiments E-M1 and E-M2 may be subjected to linear elastic deformation without a plastic deformation section.

The first embodiment E-M1 may have an elastic strain of about 2.68%, and a yield strength of about 1307 MPa. The first embodiment E-M1 may have a columnar-free amorphous structure, and thus, may have improved elastic strain and yield strength compared to the elastic strain and yield strength of a typical aluminum alloy. For example, the first embodiment E-M1 may have improved elastic strain and yield strength than the elastic strain (about 1.70%) and yield strength (about 1145 MPa) of a typical aluminum alloy disclosed in the literature, ┌A. Inoue, N. Matsumoto, T. Masumoto, Mater. Trans., vol 31, 1990, pp. 493-500┘.

The second embodiment E-M2 may have an elastic strain of about 4.73%, and a yield strength of about 2825 MPa. The second embodiment E-M2 may have a columnar-free amorphous structure, and thus, may have improved elastic strain and yield strength compared to the elastic strain and yield strength of a typical zirconium alloy. For example, the second embodiment E-M2 may have improved elastic strain and yield strength than the elastic strain (about 1.92% and about 2.16%) and yield strength (about 1630 MPa and about 2200 MPa) of a typical zirconium alloy disclosed in the literature, ┌W. L. Johnson, K. Samwer, Phys. Rev. Lett. 95, 195501┘.

Therefore, the first and second embodiments E-M1 and E-M2 may have improved elastic strain and yield strength without plastic deformation. Accordingly, the display panel DP (see FIG. 6) supported by the support layer MT (see FIG. 6) of an embodiment of the disclosure may be prevented from sagging or deforming even with repetitive folding, rolling, or bending operations.

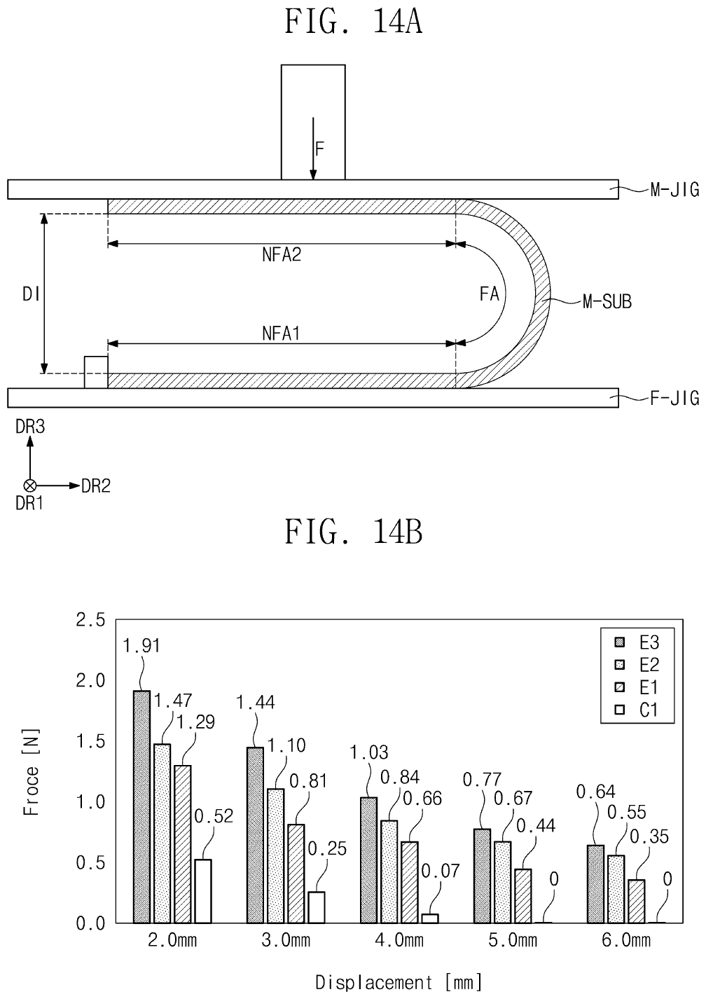

FIG. 14A is a schematic cross-sectional view illustrating a process of testing restoration force according to bending deformation of a measurement substrate M-SUB. FIG. 14B is a schematic graph illustrating restoration force according to bending deformation of embodiments E1, E2, and E3 and a comparative embodiment C1.

Referring to FIG. 14A, the measurement substrate M-SUB may be an object for testing restoration force according to bending deformation. The measurement substrate M-SUB may be disposed inside a restoration force measurement device. The restoration force measurement device may include a fixed jig F-JIG and a moving jig M-JIG. The fixed jig F-JIG and the moving jig M-JIG may face each other, and the measurement substrate M-SUB may be disposed between the fixed jig F-JIG and the moving jig M-JIG.

The fixed jig F-JIG may fix the measurement substrate M-SUB during a restoration force test process. The moving jig M-JIG may move in a downward direction parallel to the third direction DR3, and a force F may be applied to the measurement substrate M-SUB in the downward direction. In this regard, as the measurement substrate M-SUB has restoration force, reaction force applied in a direction opposing the force F may be applied to the measurement substrate M-SUB.

A folding region FA of the measurement substrate M-SUB may be folded by the restoration force measurement device. The restoration force according to bending deformation may be measured by adjusting a displacement DI between a first non-folding region NFA1 and a second non-folding region NFA2. The displacement DI may correspond to a distance between an end of the first non-folding region NFA1 and an end of the second non-folding region NFA2 in the third direction DR3.

In case that the force F applied by the moving jig M-JIG increases, the displacement DI may decrease. The restoration force of the measurement substrate M-SUB may be measured by measuring reaction force for the applied force F and the displacement DI.

Referring to FIG. 6 together, the embodiments E1, E2, and E3 of FIG. 14B may correspond to a base substrate SUB in which a support layer MT is disposed. The comparative embodiment C1 of FIG. 14B may correspond to a base substrate in which the support layer MT is not disposed. The base substrates of the embodiments E1, E2, and E3 and the comparative embodiment C1 may be the same as each other, and the base substrates SUB of the embodiments E1, E2, and E3 and the comparative embodiment C1 may include polyimide, and have a thickness corresponding to about 35 micrometers (um).

The support layers MT included in the embodiments E1, E2, and E3 may include a Zr—Cu—Co alloy in which the atomic percent of zirconium (Zr) is about 74.0 at %, the atomic percent of copper (Cu) is about 20.0 at %, and the atomic percent of cobalt (Co) is about 6.0 at %. The support layers MT included in the embodiments E1, E2, and E3 may have substantially the same alloy composition, but different thicknesses from each other. The thickness of the support layer MT of a first embodiment E1 may be about 1.2 micrometers (um), the thickness of the support layer MT of a second embodiment E2 may be about 2.4 micrometers (um), and the thickness of the support layer MT of a third embodiment E3 may be about 3.6 micrometers (um).

Referring to FIG. 14B, as the embodiments E1, E2, and E3 and the comparative embodiment C1 are folded to have a small displacement DI, it can be seen that the force F applied to the embodiments E1, E2, and E3 and the comparative embodiment C1 may increase, and restoration force corresponding thereto also may increase. However, under the same displacement (DI) condition, the comparative embodiment C1 in which the support layer MT is not deposited may have lower elastic restoration force than the embodiments E1, E2, and E3 including the support layer MT. For example, improved elastic restoration force may be achieved by depositing, on the display panel DP of the display apparatus DD, an amorphous support layer MT without a columnar structure, and permanent deformation may be prevented even with an operation such as folding or rolling.

In the first to third embodiments E1, E2, and E3, it can be seen that as the thickness of the support layer MT increases, elastic restoration force also may increase. The support layer MT may be a layer having a high elastic strain limit and restoration force, and as the thickness of the support layer MT increases, the elastic restoration force of the display apparatus DD may also improve. The thickness of the support layer MT may be designed in consideration of the elastic restoration force, thickness, flexibility, and the like required of the display apparatus DD.

The support layer MT of an embodiment of the disclosure may have improved elastic restoration force and strength, and may prevent plastic deformation (or permanent deformation) caused by stress and tensile force applied to the display apparatus DD. For example, the support layer MT may prevent the display apparatus DD from being damaged even with repeated folding, rolling, or bending of the display apparatus DD, and thus, may improve the reliability of the display apparatus DD.

A display apparatus of an embodiment of the disclosure may include a support layer having improved elastic strain limits, restoration force, and strength, so that damage or deformation of the display apparatus may be prevented even with repeated folding, rolling, or bending operations. Accordingly, the reliability of the display apparatus may improve.

A method for manufacturing a display apparatus of an embodiment of the disclosure may manufacture a display apparatus including a support layer having an improved elastic strain limit, restoration force, and strength by controlling deposition conditions of the support layer or a material of the support layer.

Although the disclosure has been described with reference to certain embodiments, it will be understood by those skilled in the art that various modifications and changes in form and details may be made therein without departing from the spirit and scope of the disclosure.

Accordingly, the technical scope of the disclosure is not intended to be limited to the contents set forth in the detailed description of the specification, but is intended to include all such modifications and changes in detail and form.

What is claimed is:

1. A display apparatus, comprising:
a display panel including a base substrate, a circuit layer, and a light emitting element which are stacked on each other; and
a support layer disposed below the base substrate and including a metal, wherein
the support layer has an elastic strain of about 2.5% or greater, and
the support layer has a yield strength of about 1200 MPa or greater.

2. The display apparatus of claim 1, wherein the support layer comprises an alloy including two or more elements among aluminum (Al), zirconium (Zr), titanium (Ti), molybdenum (Mo), copper (Cu), nickel (Ni), yttrium (Y), cobalt (Co), and silicon (Si).

3. The display apparatus of claim 2, wherein the alloy comprises at least one of aluminum (Al), zirconium (Zr), titanium (Ti), and molybdenum (Mo) in a highest atomic percent.

4. The display apparatus of claim 3, wherein the alloy is at least one of Zr—Cu—Co, Zr—Cu—Si, Zr—Cu—Al—Ni, Al—Y—Ni—Co, Ti—Si—Zr—Mo, and Mo—Zr—Si—Ti.

5. The display apparatus of claim 2, wherein
the alloy is at least one of Zr—Cu—Co, Zr—Cu—Si, and Zr—Cu—Al—Ni, and
an atomic percent of zirconium in the alloy is in a range of about 50 at % to about 90 at %.

6. The display apparatus of claim 5, wherein the support layer has an elastic strain in a range of about 4.6% to about 4.9%.

7. The display apparatus of claim 5, wherein the support layer has a yield strength in a range of about 2700 MPa to about 2900 MPa.

8. The display apparatus of claim 2, wherein
the alloy is Al—Y—Ni—Co, and
an atomic percent of aluminum in the alloy is in a range of about 50 at % to about 85 at %.

9. The display apparatus of claim 8, wherein the support layer has an elastic strain in a range of about 2.5% to about 2.8%.

10. The display apparatus of claim 8, wherein the support layer has a yield strength in a range of about 1200 MPa to about 1400 Mpa.

11. The display apparatus of claim 2, wherein the alloy has a columnar-free amorphous structure.

12. The display apparatus of claim 1, wherein
the base substrate comprises:
a first surface on which the circuit layer is disposed; and
a second surface opposing the first surface, and
the support layer physically contacts the second surface.

13. The display apparatus of claim 1, further comprising:
a synthetic resin film disposed below the display panel and including at least one of polyimide and polyethylene terephthalate,
wherein the support layer physically contacts the synthetic resin film.

14. The display apparatus of claim 1, wherein the display panel and the support layer are folded or rolled around an axis extended in a direction.

15. The display apparatus of claim 14, further comprising:
a support plate disposed below the display panel, and including stainless steel or a reinforced fiber,
wherein the support layer physically contacts the support plate.

16. A method for manufacturing a display apparatus, the method comprising:
providing a processing substrate;
ion-etching a surface of the processing substrate; and
forming a support layer including a metal on the ion-etched surface using a sputtering process, wherein
the support layer has an elastic strain of about 2.5% or greater; and
the support layer has a yield strength of about 1200 MPa or greater.

17. The method of claim 16, wherein the sputtering process is a high-frequency pulsed-DC magnetron sputtering process.

18. The method of claim 17, wherein in the high-frequency pulsed-DC magnetron sputtering process, a density of power applied to a target layer for forming the support layer including a metal is in a range of about 4 W/cm² to about 5 W/cm².

19. The method of claim 18, wherein
the target layer is formed by:
manufacturing a master alloy by selecting an alloying element;
forming metal powder from the master alloy; and
sintering the metal powder, and
the alloying element includes two or more elements among aluminum (Al), zirconium (Zr), titanium (Ti), molybdenum (Mo), copper (Cu), nickel (Ni), yttrium (Y), cobalt (Co), and silicon (Si).

20. The method of claim 19, wherein
a temperature at which the metal powder is sintered is equal to or greater than a glass transition temperature of the alloying element, and
the temperature at which the metal powder is sintered is equal to or less than a crystallization temperature thereof.
